(19) United States
(12) Patent Application Publication
(10) Pub. No.: US 2024/0222064 A1
(43) Pub. Date: Jul. 4, 2024

(54) Processor System, Correction Method, and Correction Program

(71) Applicant: Hitachi High-Tech Corporation, Tokyo (JP)

(72) Inventors: Mayuka OSAKI, Tokyo (JP); Shgunki Tsuboya, Tokyo (JP); Hajime Kawano, Tokyo (JP)

(21) Appl. No.: 18/390,046

(22) Filed: Dec. 20, 2023

(30) Foreign Application Priority Data
Dec. 28, 2022 (JP) 2022-211504

(51) Int. Cl. H01J 37/153; H01J 37/22; H01J 37/244; H01J 37/285; H01J 37/30; H01J 37/304

(52) U.S. Cl. CPC H01J 37/153; H01J 37/222; H01J 37/226; H01J 37/244; H01J 37/3005; H01J 37/3045; H01J 37/285; H01J 2229/507; H01J 2231/50047

(57) ABSTRACT

A multi-beam charged-particle microscope apparatus 100 includes an irradiation system 104 that irradiates a plurality of regions on a surface of a sample 9 with a plurality of beams, a detection system 125 (correction detector 132 and imaging detector 131) that detects emitted electrons from the surface of the sample 9, and a controller 102 that generates a first brightness of a first pixel in a first region based on a first signal of a first detector of a multi-detector 123 and generates a second brightness of a second pixel in a second region based on a second signal of a second detector. A processor of a processor system 103 that can communicate with the charged-particle microscope apparatus 100 specifies a first crosstalk amount from a second emitted electron to the first signal based on the first brightness obtained from the charged-particle microscope apparatus 100 and an output of the correction detector 132 and corrects the first brightness based on the first crosstalk amount.

### BACKGROUND OF THE INVENTION

### 1. Field of the Invention

The present disclosure relates to a technology for a processor system connected to a charged-particle microscope apparatus.

### 2. Description of Related Art

For example, as a device having a function for high-speed observation, measurement, evaluation, and inspection of a sample such as a semiconductor wafer, a multi-beam charged-particle microscope apparatus that irradiates the sample with a plurality of charged particle beams (typically electron beams) as a multi-beam has appeared. In the multi-beam charged-particle microscope apparatus, a phenomenon called so-called crosstalk may occur regarding a detection signal based on the multi-beam.

In the multi-beam charged-particle microscope apparatus, each of emitted electrons, such as secondary electrons and back-scattered electrons, generated from the sample based on each of electron beams of the multi-beam is detected by each of a plurality of detectors. Especially, in the case of a scanning type multi-beam charged-particle microscope apparatus, each of a plurality of regions on a sample surface is irradiated with each electron beam of the multi-beam so as to be scanned with the electron beam, and a plurality of emitted electrons from the plurality of regions are detected by the plurality of detectors.

In this case, in a conventional multi-beam charged-particle microscope apparatus, normally, that is, when there is no crosstalk, an emitted electron generated from a pixel in a certain region (for example, first region) based on irradiation with a certain electron beam (for example, first beam) is detected as a first signal by a certain detector (for example, first detector) corresponding to that electron beam, and an emitted electron generated from a pixel in a certain region (for example, second region) based on irradiation with another electron beam (for example, second beam) is detected as a second signal by another detector (for example, second detector) corresponding to that electron beam. On the other hand, when there is crosstalk, for example, the emitted electron based on the second beam should be detected by the second detector, but may deviate from a trajectory thereof, enter a detection range of the first detector to be mixed therewith, and detected as the first signal together with emitted electron based on the first beam. Such a phenomenon is sometimes referred to as crosstalk.

Examples of related art include JP2020-511733A (PTL 1). PTL 1 describes a charged particle beam system and method, and states a feature of “the charged particle beam system comprising a charged particle source configured to generate a first charged particle beam, a multi beam generator configured to generate a plurality of charged particle beamlets from an incoming first charged particle beam, in which each individual beamlet of the plurality of charged particle beamlets is spatially separated from other beamlets of the plurality of charged particle beamlets, an objective lens configured to focus incoming charged particle beamlets in a first plane in a manner that a first region in which a first individual beamlet of the plurality of charged particle beamlets impinges in the first plane is spatially separated from a second region in which a second individual beamlet of the plurality of charged particle beamlets impinges in the first plane, a projection system, and a detector system including a plurality of individual detectors, wherein the projection system is s configured to image interaction products leaving the first region within the first plane due to impinging charged particles onto a first one of the plurality of individual detectors and to image interaction products leaving the second region in the first plane due to impinging charged particles onto a second one of the plurality of individual detectors”.

The multi-beam charged-particle microscope apparatus described above has an essential problem in that crosstalk may occur between emitted electrons based on the multi-beam. Therefore, the multi-beam charged-particle microscope apparatus requires a countermeasure against such crosstalk.

Factors that cause crosstalk in the multi-beam charged-particle microscope apparatus include sample charging and insufficient optical adjustment. In the case of sample charging, a state of charging on the sample surface on a stage may change over time and locally. Depending on a state of the sample charging, a trajectory of the emitted electron generated from the sample surface based on the electron beam may change, and a detection position at which the emitted electron is detected within a detection range of a detector may change. Such a change appears as crosstalk. In other words, when viewing a plurality of detection signals from a plurality of detectors of a multi-detector, the influence of crosstalk may occur locally and over time between the detection signals.

In the multi-beam charged-particle microscope apparatus, an image is generated based on the plurality of detection signals of the plurality of detectors. That is, one captured image is generated by combining a plurality of captured images obtained from the plurality of detection signals. This generated image (which may be described as real image), when there is crosstalk, becomes an image whose image content is shifted from an image (which may be described as ideal image) when there is no crosstalk. An image that deviates from the ideal image due to the influence of crosstalk in this way is sometimes referred to as a ghost image. This ghost image is a phenomenon that occurs between a plurality of captured images simultaneously captured by the multi-beam and the plurality of detectors due to the influence of crosstalk. This ghost image refers to, for example, the fact that the second image captured by the second detector or a part thereof is superimposed on the first image captured by the first detector, or the superimposed portion thereof.

When the ghost image occurs due to the influence of the crosstalk described above, as a countermeasure, it is required to obtain an image as close to the ideal image as possible.

In addition, in PTL 1, in the charged particle beam system device, the common elements (for example, elements 250 to 281 in FIG. 4) provided between the multi-beam generator and the multi-detector control the trajectory of the plurality of emitted electrons corresponding to the plurality of charged particle beams. PTL 1 is not a technology for dealing with crosstalk based on the detection signals from the multi-detector. Therefore, with the technology such as PTL 1, it is difficult to deal with the case where crosstalk occurs for the emitted electron corresponding to a specific beam among the multi-beam due to factors such as local sample charging.

### SUMMARY OF THE INVENTION

An object of the present disclosure is to provide a technology that can reduce the influence of crosstalk regarding the multi-beam charged-particle microscope apparatus.

A representative embodiment of the present disclosure has the configuration shown below. An embodiment is a processor system that is able to communicate with a charged-particle microscope apparatus, the charged-particle microscope apparatus includes a charged particle beam irradiation system that includes at least one charged particle source, and irradiates a first region on a sample surface with a first charged particle beam generated using the charged particle source while irradiating a second region on the sample surface with a second charged particle beam generated using the charged particle source, a detection system including a correction detector that detects a first emitted electron emitted from the first region and a second emitted electron emitted from the second region, a first detector that detects the first emitted electron through a part of the correction detector and outputs a first signal, and a second detector that detects the second emitted electron through a part of the correction detector and outputs a second signal, and a controller that generates a first brightness of a first pixel corresponding to a first position within the first region based on the t signal and generates a second brightness of a second pixel corresponding to a second position within the second region based on the second signal, the processor system includes one or more memory resources and one or more processors, the processor (A) stores first brightness and an output of the correction detector acquired from the charged-particle microscope apparatus in the memory resource, (B) specifies a first crosstalk amount from the second emitted electron to the first signal, regarding the amount detected by the first detector, based on the output of the correction detector, and (C) corrects the first brightness based on the first crosstalk amount.

According to representative embodiments of the present disclosure, the influence of crosstalk regarding the multi-beam charged-particle microscope apparatus can be reduced. Problems, configurations, effects, and the like other than those described above are illustrated in the detailed description.

### BRIEF DESCRIPTION OF THE DRAWINGS

FIG. 1 illustrates a configuration of a system including a multi-beam charged-particle microscope apparatus and a processor system according to Embodiment 1;

FIG. 2 illustrates a main processing flow of the processor system of Embodiment 1;

FIG. 3 illustrates a sequence of processing operations in the system including the processor system of Embodiment 1;

FIG. 4 is a schematic explanatory diagram of irradiation of a plurality of regions on a sample surface with a multi-beam, generated emitted electrons, detection in a scintillator, and the like in Embodiment 1;

FIG. 5 illustrates a schematic explanatory diagram regarding a detection range and an emitted electron light amount distribution on a surface of the scintillator of the correction detector in Embodiment 1;

FIG. 6 illustrates a configuration example of a scintillator and a multi-detector of an imaging detector in Embodiment 1;

FIG. 7 illustrates a schematic explanatory diagram regarding trajectories and detection of emitted electrons when a virtual lens occurs locally on the sample surface in Embodiment 1;

FIG. 8 illustrates a schematic explanatory diagram regarding an example of the emitted electron light amount distribution on the surface of the scintillator when the virtual lens occurs in Embodiment 1;

FIGS. 9A and 9B illustrate a schematic explanatory diagram regarding another example of when the virtual lens occurs locally on the sample surface in Embodiment 1;

FIG. 10 illustrates a schematic explanatory diagram regarding an example of the emitted electron light amount distribution on the surface of the scintillator when another example of the virtual lens occurs;

FIG. 11 illustrates a calculation formula for crosstalk influence correction in Embodiment 1;

FIG. 12 illustrates a schematic explanatory diagram of a plurality of images generated based on a plurality of signals of a plurality of detectors in a multi-detector corresponding to scanning of a plurality of regions on the sample surface with a multi-beam in Embodiment 1;

FIG. 13 illustrates an example in which images before and after correction are displayed on a screen in Embodiment 1; and

FIG. 14 illustrates a schematic explanatory diagram of irradiation of a plurality of pixels on a sample surface with a multi-beam and a plurality of generated pixel images in Modification 1 of Embodiment 1.

### DESCRIPTION OF EMBODIMENTS

Embodiments of the present disclosure will be described in detail below with reference to the drawings. In the drawings, the same parts are generally denoted by the same reference numerals, and repeated explanations are omitted. In the drawings, representations of components may not represent their actual positions, sizes, shapes, ranges, and the like in order to facilitate understanding of the invention. The following embodiments (also referred to as examples) described below are merely examples, and should not be construed as limiting, and specific configurations may be changed in various ways without departing from the idea and gist of the present disclosure.

For the purpose of explanation, when explaining processing by a program, the program, a function, a processing unit, and the like are sometimes described as a main body, but the main body of hardware for these is a processor or a controller, an apparatus, a computer, a system, and the like, composed of the processor and the like. The computer executes processing according to the program read onto a memory while using resources such as the memory and a communication interface as appropriate, by the processor. With this configuration, a predetermined function, the processing unit, and the like are realized. The processor is configured with, for example, a semiconductor device such as a CPU/MPU or a GPU. The processing is not limited to software program processing, but can also be implemented with a dedicated circuit. As the dedicated circuit, FPGA, ASIC, CPLD, and the like can be adopted.

The program may be installed in advance as data on a target computer, or may be distributed as data from a program source to the target computer. The program source may be a program distribution server on a communication network or a non-transitory computer-readable storage medium such as a memory card or disk. The program may be composed of a plurality of modules. A computer system may be configured with a plurality of devices. The computer system may be configured with a client/server system, a cloud computing system, an IoT system, and the like. Various types of data and information are composed of, for example, structures such as tables or lists, but are not limited thereto. Expressions such as identification information, identifier, ID, name number, and the like can be replaced with each other.

### [Supplementary Information on Problems and the Like]

One of the factors of crosstalk that can occur in the multi-beam charged-particle microscope apparatus is the sample charging described above. Sample charging can occur and change over time and locally. The phenomenon of sample charging may be different depending on, for example, a material and pattern structure of a target sample, a processing process, a structure and environment of a microscope apparatus, and the like. Other factors include insufficient optical adjustment, for example, deviation in alignment or deviation in focus adjustment. Crosstalk can also occur due to a combination of a plurality of factors. Therefore, it is difficult to predict the occurrence of crosstalk in advance. For example, inside the multi-beam charged-particle microscope apparatus, it is difficult to grasp in advance a change in the trajectory of the emitted electrons due to sample charging and to adjust and deal with the change.

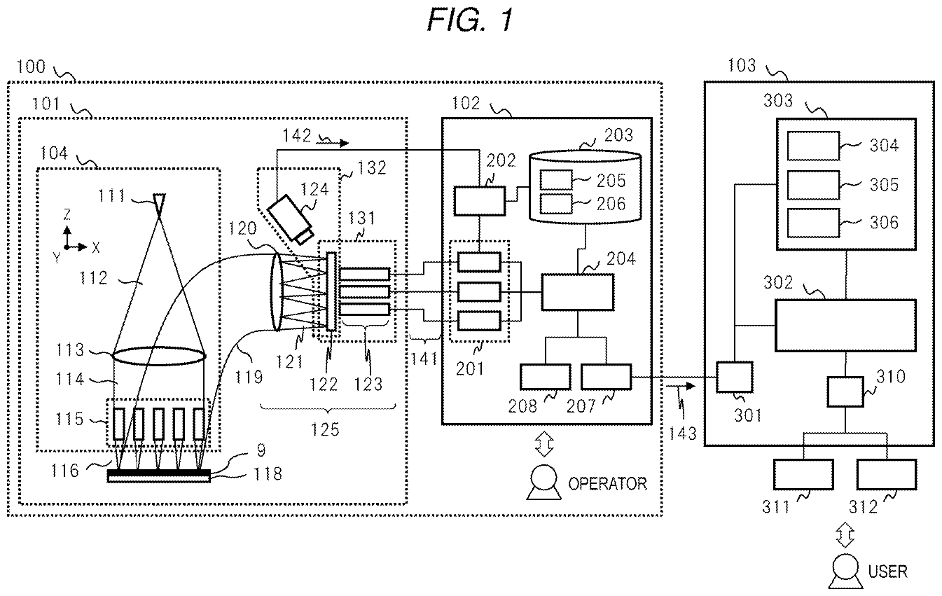

In contrast, a processor system 103 (FIG. 1) of the embodiment performs correction for reducing crosstalk influence generated inside the charged-particle microscope apparatus on received and input images, and the like (data 143) outputted from a multi-beam charged-particle microscope apparatus 100, and obtains the corrected image and the like.

In the embodiment, inside the multi-beam charged-particle microscope apparatus 100 (FIG. 1), a state in which a plurality of emitted electrons generated from a sample surface based on irradiation of the multi-beam are incident on a surface of a scintillator 122 of a correction detector 132, which is a common element, and are converted into photons is imaged and observed by an observation device 124. As an output of the observation device 124, a captured image for correction is obtained. In the captured image for correction, a plurality of image regions corresponding to a plurality of detection ranges of a plurality of detectors of a multi-detector 123 are included.

The plurality of detectors as the multi-detector 123 are arranged behind the scintillator 122 (FIG. 1). Each detector is an element, for example, a photomultiplier, that converts photons corresponding to emitted electrons that have entered the detection range into an electrical signal (also referred to as a detection signal or an output signal) and detects the signal. A plurality of detection signals 141 are obtained as outputs of the multi-detector 123. A controller 102 of the multi-beam charged-particle microscope apparatus 100 obtains a captured image based on a multi-beam from the plurality of detection signals 141 that are the outputs of the multi-detector 123.

The processor system 103 (FIG. 1) obtains data/information (data 143) including the captured image and the captured image for correction described above from the controller 102 of the multi-beam charged-particle microscope apparatus 100. The processor system 103 calculates the crosstalk influence among the plurality of detectors of the multi-detector 123 from the emitted electron light amount distribution in the captured image for correction described above. The processor system 103 performs correction for reducing the crosstalk influence on the real image, which is a captured image based on the multi-detector 123, and as a result of the correction, obtains an image close to the ideal image, or at least an image with reduced crosstalk influence than the real image. Correction is an operation that reflects the calculated crosstalk influence.

According to the correction of crosstalk influence by the processor system 103 of the embodiment, even if, for example, crosstalk caused by temporal or local sample charging, occurs and influences the emitted electrons and the captured image based on the multi-beam, an image in which crosstalk influence is eliminated or reduced can be obtained as an image which is a final output result. Even if a ghost image occurs in the real image which is the captured image, an image in which the ghost image is eliminated or reduced can be obtained in a corrected image.

### [Solution and the Like]

As a means for solving the problem, a processor system or the like according to the following embodiments is provided.

(1) A processor system of the embodiment is the processor system 103 (FIG. 1) that can communicate with the multi-beam charged-particle microscope apparatus 100. The charged-particle microscope apparatus 100 includes a charged particle beam irradiation system 104 that includes at least one charged particle source, and irradiates a first region on a sample surface with a first charged particle beam generated using the charged particle source while irradiating a second region on the sample surface with a second charged particle beam generated using the charged particle source, a detection system 125, and the controller 102. The detection system 125 includes a correction detector 132 (a set of the scintillator 122 and an observation device 124) that detects a first emitted electron emitted from the first region and a second emitted electron emitted from the second region, and the multi-detector 123 including a first detector (one detector of the multi-detector 123) that detects the first emitted electron through a part (scintillator 122) of the correction detector 132 and outputs a first signal, and a second detector (the other one of the multi-detectors 123) that detects the second emitted electron through a part (scintillator 122) of the correction detector 132 and outputs a second signal.

The controller 102 generates a first brightness of a first pixel corresponding to a first position within the first region based on the first signal of the detection signals 141 and generates a second brightness of a second pixel corresponding to a second position within the second region based on the second signal of the detection signals 141. The processor system 103 includes one or more memory resources (for example, memory 303) and one or more processors (for example, memory processor 302). The processor 302 (A) stores data 143 including the first brightness and the captured image for correction, which is an output of the correction detector 132, acquired from the charged-particle microscope apparatus 100 in the memory resource, (B) specifies a first crosstalk amount from the second emitted electron to the first signal, regarding an amount detected by the first detector, based on the output of the correction detector 132, and (C) corrects the first brightness based on the first crosstalk amount.

According to a configuration of the (1) described above, for example, when attention is focused on the first pixel and second pixel in an image, the crosstalk amount from the second pixel to the first pixel is calculated, and the brightness of a signal of the first pixel is corrected based on the crosstalk amount. According to the configuration of the (1) described above, since the first brightness can be corrected independently of the second brightness, the correction can be performed accurately so as to reduce the influence of crosstalk. According to the configuration of the (1) described above, the influence of crosstalk can be reduced for each individual beam of the multi-beam. Therefore, even when the influence of crosstalk is different for each beam, coping is possible. For example, even when a state of sample charging is not uniform on the sample surface and the state of sample charging occurs and changes locally and over time, the influence of crosstalk caused by the sample charging can be reduced.

An example of a change in sample charging over time is that a charged amount increases in an irradiated region due to irradiation with a primary charged particle beam. An example of a local change in sample charging is that the charging amount is different for each local region depending on the material, pattern shape, processing process, and the like on the sample surface.

(2) In the processor system 103 of the (1) described above, the controller 102 generates a first image including the first pixel as generation of the first brightness of the first pixel, and generates a second image including the second pixel as generation of the second brightness of the second pixel. In other words, the first pixel is a part of the first image created corresponding to the first region and the second pixel is a part of the second image created corresponding to the second region.

(3) In the processor system of the (1) described above, the correction detector includes, for example, a scintillator 122, which is a light emitting element that emits light at a collision position with the first emitted electron and a collision position with the second emitted electron, and for example, an observation device 124, which is an imaging element that images the light emitting element. An output of the correction detector 132 includes a captured image for correction captured using the imaging element. The first detector of the multi-detector 123 includes an element that detects light emission in a first detection range of the light emitting element in order to detect the first emitted electron, and the second detector thereof includes an element that detects light emission in a second detection range of the light emitting element in order to detect the second emitted electron. Specifying the first crosstalk amount in the (B) described above includes specifying an amount of the second emitted electron included in the first detection range based on the captured image for correction.

According to a configuration of the (3) described above, by using the light emission of the light emitting element, which is shared by the correction detector 132, the first detector, and the second detector, and which exists on a main path of the emitted electrons, it becomes possible to specify the amount of crosstalk with higher accuracy. According to the configuration of the (3) described above, since there is no need to prepare a scintillator that performs detection for correction separately from the scintillator for imaging, the structure is simpler, and there is no need for a mechanism for dividing the emitted electrons into scintillators of two uses. Furthermore, according to the configuration of the (3) described above, it is not a configuration in which the crosstalk influence is corrected inside the charged-particle microscope apparatus 100, but a configuration in which the crosstalk influence is corrected on the processor system 103 side using an image output from the charged-particle microscope apparatus 100 and the like. Therefore, according to the configuration of the (3) described above, on the processor system 103 side, it is easy to utilize abundant image processing library software for captured images, and it is possible to continuously improve the accuracy of specifying the crosstalk amount at low development cost.

(4) In the processor system 103 of the (3) described above, the charged particle beam irradiation system 104 further irradiates a third region on the sample surface with a third charged particle beam. The detection system 125 further includes a third detector that detects a third emitted electron emitted from the third region through a part of the correction detector 132 and outputs a third signal. The third detector includes an element that detects light emission in a third detection range of the light emitting element for detecting the third emitted electron. The processor 302 (D) specifies a second crosstalk amount from the third emitted electron to the first signal based on an output of the correction detector 132 and (E) corrects the first brightness based on the second crosstalk amount, and specifies the second crosstalk amount in the (D) described above includes specifying an amount of second emitted electrons included in the first detection range based on the captured image for correction.

According to the configuration of the (4) described above, even if crosstalk influence from both the second region and the third region occurs on the first region, correction for reducing the crosstalk influence on the first region can be made.

(5) In the processor system 103 of the (3) described above, the captured image for correction has a first image region corresponding to the first detection range of the light emitting element, a second image region corresponding to the second detection range of the light emitting element, and a third image region corresponding to the third detection range of the light emitting element. In the (B) described above, the processor 302 specifies the first crosstalk amount to a value greater than zero when a first light emitting region extending from the second image region into the first image region exists, and, in the (D) described above, the processor 302 specifies the second crosstalk amount to a value greater than zero when a second light emitting region extending from the third image region into the first image region exists.

In the configuration of the (5) described above, positions and regions where the first, second, and third image regions in the captured image for correction, that are respectively associated with the first, second, and third detection ranges of the multi-detector 123, are located are designed and set in advance in the processor system 103 or the like. For example, in a correction program 304, such information is set as parameters and algorithms.

(6) In the processor system 103 of the (5) described above, the controller 102 generates the first image including the first pixel as generation of the first brightness of the first pixel, and generates the second image including the second pixel as generation of the second brightness of the second pixel. An imaging period of the captured image for correction imaged by an imaging element of the correction detector 132 is a period matching an imaging period of the first image of the first detector of the multi-detector 123 or an imaging period of the first pixel.

As an embodiment, either a system (a general term that includes a method, a device, and the like) for performing crosstalk influence correction in image units (between images in the detection range described below) or a system for performing crosstalk influence correction in pixel units (between pixels of images in the detection range described below) is possible. The former image unit refers to processing between a plurality of images by a plurality of detection signals of a plurality of detectors (corresponding a plurality of detection ranges) of the multi-detector 123 based on irradiation (especially scanning) of a plurality of regions on the sample surface with the multi-beam. The latter pixel unit refers to processing between images of a plurality of pixels by the plurality of detection signals of the plurality of detectors (corresponding a plurality of detection ranges) of the multi-detector 123 based on irradiation of a plurality of regions (especially a plurality of pixels) on the sample surface with the multi-beam. A plurality of pixels are included in the former image unit.

In Embodiment 1, a system for performing crosstalk influence correction in image units will be mainly described. Depending on the system used, the period (for example, exposure period) during which the observation device 124, which is an imaging element of the correction detector 132, captures the captured image for correction is designed as a period corresponding to the period during which each detector of the multi-detector 123 detects an image.

(7) In the processor system 103 of the (5) described above, the processor 302 (F) stores the second brightness acquired from the charged-particle microscope apparatus 100 in the memory resource, and (G) corrects the second brightness based on at least the first crosstalk amount. Correction of the second brightness correction of the (G) described above also includes a correction amount of the second brightness based on a correction amount of the correction of the first brightness based on the first crosstalk amount of the (C) described above.

According to the configuration of the (7) described above, it is possible to correct not only the first brightness but also the second brightness of the (1) described above.

According to the present disclosure, there are provided correction method and correction program corresponding to the processor system of each of the embodiments as in the (1) to (7) described above. The correction method is a method executed by the processor system. The correction program is a computer program that causes the processor system to perform correction processing, and is stored, for example, in a non-transitory computer-readable storage medium.

### Embodiment 1

A processor system and the like according to Embodiment 1 of the present disclosure will be described using FIGS. 1 to 13.

### [Summary of Embodiment 1]

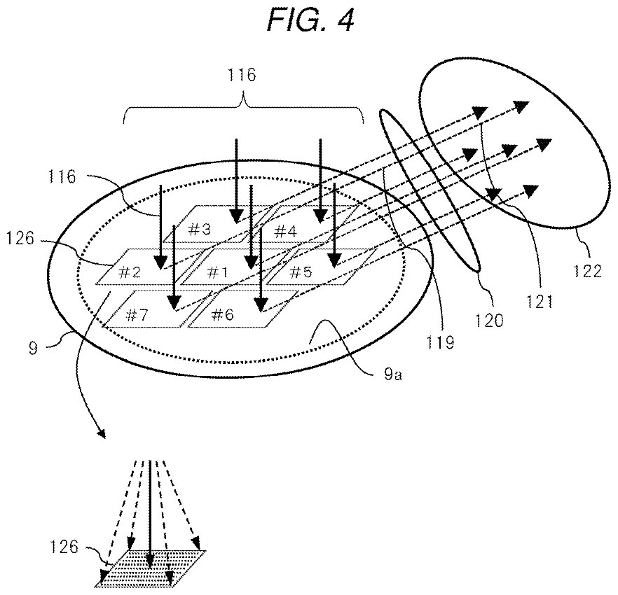

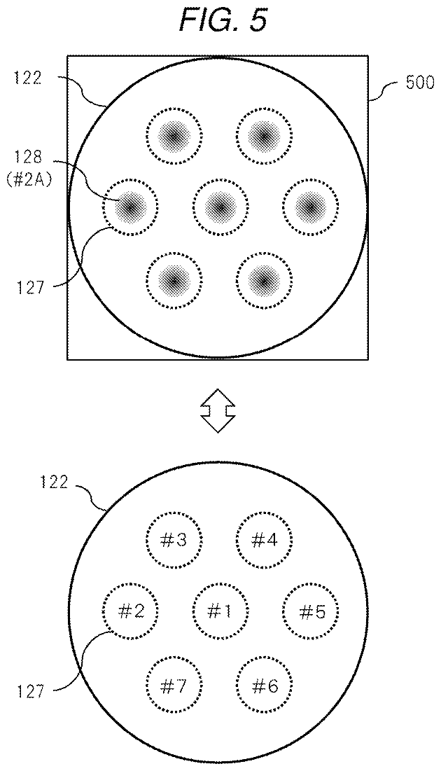

The system 103 (FIG. 1) of Embodiment 1 performs correction for reducing crosstalk influence on a captured image based on a plurality of signals 141 that are the outputs of the plurality of detectors of the multi-detector 123, and obtains a corrected image. In this correction, a plurality of emitted electrons 119 (this plurality corresponds to the plurality in the plurality of multi-beams) generated from regions 126 of a sample 9 based on irradiation with a plurality of charged particle beams 116, which are the multi-beam 116 (FIG. 4), are incident on and collide with a surface of the scintillator 122, which is a part of the correction detector. The incident and collided emitted electrons are converted into photons by the action of the scintillator 122. Each converted photon is incident on a detection range 127 (FIG. 5) of a corresponding detector of the multi-detector 123 behind the scintillator 122 depending on the position. Each detector converts photons incident on the detection range 127 into an electrical signal (in other words, a detection signal, an output signal), and detects and outputs the signal.

The scintillator 122 is a common element for the multi-detector 123. The surface of the scintillator 122 includes a plurality of detection ranges 127 corresponding to a plurality of detectors. For example, a CCD camera, which is the observation device 124, images a state of a light amount distribution of the plurality of emitted electrons incident on or emitted from the surface of the scintillator 122 as a captured image for correction.

Respective detection ranges 127 are associated with respective image regions within the captured image for correction. For example, in an ideal state with no crosstalk, a first emitted electron generated based on irradiation with a first charged particle beam is incident on a first detection range corresponding to a first detector and forms a first image region within the captured image for correction. The first detector outputs a first signal obtained based on the emitted electrons incident within the first detection range. Similarly, a plurality of signals 141 from the plurality of detectors of the multi-detector 123 are obtained, and the controller 102 combines the signals 141 to generate a captured image.

The processor system 103 determines and calculates, based on data 143 obtained from the controller 102, the crosstalk influence, such as the degree of mixing, between the detection ranges 127, that is, between the detectors, regarding photons of emitted electrons passing through each of the plurality of detection ranges 127 on the surface of the scintillator 122 based on the captured image for correction.

In Embodiment 1, as the crosstalk influence, it is possible to consider mixing of emitted electrons from other detection ranges 127 (for example, second region or second pixel) to the own detection range 127 (for example, first region or first pixel), outflow of emitted electrons from the own detection range to other detection ranges, or the residual emitted electrons within the own detection range after subtracting the outflow of emitted electrons, and the like, for each detection range 127 of each detector of the multi-detector 123, in other words, for each image region corresponding thereto. The calculation formulas (F=CAR, and the like) described below reflect the concept of such crosstalk influence.

For example, the processor system 103 can correct the captured image so as to quantify the crosstalk influence as a crosstalk influence coefficient based on the idea of mixing rate and residual rate in the plurality of detection ranges 127, and reduce the crosstalk influence using the crosstalk influence coefficient.

The controller 102 generates a plurality of image signals (in other words, the captured images) corresponding to the plurality of regions 126 on the surface of the sample 9 and the plurality of detection ranges 127 based on the plurality of signals 141 including the signal 141 for each detector as the output of multi-detector and the 123, transmits data corresponding to the signals to the processor system 103. The processor system 103 performs correction processing for reducing crosstalk influence on the plurality of image signals (in other words, captured images) and obtains the corrected image.

In Embodiment 1, as an example of a means for determining the crosstalk influence, in other words, a means for calculating the crosstalk influence coefficient, the state of the light emission distribution of the plurality of emitted electrons on the surface of the scintillator 122 in the front stage of the multi-detector 123 is imaged by the observation device 124. The processor system 103 quantifies the position and intensity distribution of emitted electron light in the plurality of detection ranges 127 using the captured image for correction by the observation device 124.

Then, the processor system 103 calculates the crosstalk influence coefficient from the result of quantifying the emitted electron light emission distribution and the like as the content of the captured image for correction. For example, when light of the emitted electrons extends and is distributed from inside the second image region to inside the first image region between a first image region corresponding to a certain first detection range and a second image region corresponding to another second detection range, it can be determined that there is the crosstalk influence from the second detection range (second emitted electron corresponding thereto and the like) to the first detection range, in other words, there is mixing of an extra amount of light into the first detection range. Or, conversely, when the emitted electron light extends and is distributed from inside the first image region to inside the second image region, it can be determined that there is the crosstalk influence from the first detection range to the second detection range, in other words, there is outflow of the amount of light from the first detection range. When considering the first detection range as an own region, it can be determined that there is a residual amount within the first detection range excluding the amount that has flowed out of the first detection range. The same applies to other detection ranges 127 and image regions. By integrating all the crosstalk influences of captured images of the multi-detector 123, the crosstalk influence can be quantified for each detection range 127.

Based on the processing of the captured image for correction, the processor system 103 evaluates the degree of mixing and outflow of emitted electrons between the own detection range 127 and other detection ranges 127 as the crosstalk influence coefficient for each image of the detection range 127 regarding the image signal of the detection range 127 of each detector of the multi-detector 123. In this case, the processor system 103 calculates the position and shape of the image region of each detection range 127, the position and shape of the emitted electron light amount distribution 128, the light amount (brightness corresponding to the amount of light), and the like in the captured image for correction, and calculates the mixing rate, the residual rate, between the detection ranges 127 and the like.

The processor system 103 performs correction processing for reducing the crosstalk influence using the captured image based on the output of the multi-detector 123 and the calculated crosstalk influence coefficient. For example, based on the mixing rate of light mixing from the second detection range to the first detection range, the first image signal of the first detector in the first detection range is corrected so that the mixing of light from the second detection range to the first detection range approaches zero. As a result, the first image signal of the first detector in the first detection range provides an image close to the ideal image when there is no crosstalk influence. The same applies to images of other detection ranges 127.

A correction program 304 for the correction processing described above is stored in the memory resource of the processor system 103. The processor 302 executes correction processing according to the correction program 304. The processor receives and acquires at least the captured image for correction of the output of the observation device 124 and the signal 141 of the output of multi-detector 123 or a captured image generated based on the signal 141 from the controller 102 of the charged-particle microscope apparatus 100. The signal 141 of the output of the multi-detector 123 includes at least the first image signal (first signal) of the output of the first detector having the first detection range and the second image signal (second signal) of the output of the second detector having the second detection range.

The controller 102 or the processor system 103 generates respective images from the signal 141 of the multi-detector 123. The controller 102 or the processor system 103 generates a first brightness of a first pixel at a first position in a first region on the surface of the sample 9 based on a first signal of the first detector, and generates a second brightness of a second pixel at a second position in a second region on the surface of the sample 9 based on a second signal of the second detector.

The processor 302 of the processor system 103 calculates the crosstalk influence between the detection ranges 127 as the crosstalk influence coefficient (for example, mixing rate and residual rate) based on the analysis of the content of the captured image for correction. In this case, the processor 302 specifies the crosstalk amount (for example, mixing amount) from the second emitted electrons to the first signal as the crosstalk influence coefficient. Then, the processor system 103 performs correction processing using the crosstalk influence coefficient on the captured image (for example, the first brightness of the first pixel or the second brightness of the second pixel), which is a real image, to obtain a corrected image (for example, first brightness and second brightness after correction) in which the crosstalk influence is reduced. For example, the processor 302 corrects the first brightness of the first pixel based on the specified amount of crosstalk. As a result, the first brightness of the first pixel after correction becomes a brightness in which excess brightness is reduced so that the mixing amount from the second emitted electrons is removed.

### [Regarding Scanning Type Charged-Particle Microscope Apparatus]

Although there are charged-particle microscope apparatus including a type of charged-particle microscope apparatus that scans the sample surface with a charged particle beam and a type of charged-particle microscope apparatus that does not scan the sample surface with a charged particle beam, in Embodiment 1, a case in which the charged-particle microscope apparatus 100 has a scanning type configuration in which the multi-beam 116 scans the surface of the sample 9 is described. The charged-particle microscope apparatus 100 is a scanning electron microscope.

This scanning electron microscope irradiates each region 126 (FIG. 4) on the surface of the sample 9 with each charged particle beam 116 of the multi-beam 116 generated by the irradiation system 104 such that each region 126 is scanned. In response to the irradiation, each emitted electron 119 associated with each charged particle beam 116 is generated from each region 126 on the surface of the sample 9. Each of the emitted electrons 119 becomes an emitted electron 121 converged through a converging lens 120, is incident on and collides with the surface of the scintillator 122 of an imaging detector 131 and is converted into photons, is incident on each detector of the multi-detector 123 located at a rear stage of the scintillator 122, and is detected as the signal 141 (in other words, image signal, detection signal, output signal).

The controller 102 generates a captured image of each region 126 from a plurality of signals 141 that are outputs of the multi-detector 123 of the imaging detector 131. In the scanning type charged-particle microscope apparatus, since scanning is performed on a group of pixels within the region 126 in time series, a captured image corresponding to the region 126 is obtained by combining the plurality of signals 141 corresponding to the group of pixels in time series. The captured image becomes an image that reflects the device structure of the region 126 on the surface of the sample 9 and the like.

In Embodiment 1, an example in which the processor system 103 connected to the multi-beam charged-particle microscope apparatus 100 through communication, based on data 143 such as the captured image and the like output from the charged-particle microscope apparatus 100, specifies the amount of crosstalk related to the crosstalk occurring inside the charged-particle microscope apparatus 100, in other words, evaluates and quantifies the crosstalk influence, and the like, and corrects the brightness of the captured image so as to reduce the crosstalk influence will be described.

In Embodiment 1, a case in which the crosstalk influence between the detection ranges 127 on the signal 141 and captured image for each region 126 and for each detector output from the scanning type charged-particle microscope apparatus 100 is calculated, and the crosstalk influence between these detection ranges 127 is corrected as image-by-image correction will be described.

For the purpose of explanation, a case will be described assuming that there are a large number of emitted electrons emitted from each region 126. In this case, the “converged emitted electron 121” becomes the converged emitted electron beam 121. Similarly, the “emitted electron 119” becomes the emitted electron beam 119. Furthermore, for the purpose of explanation, a state in which there is no crosstalk is assumed to be an ideal or standard state. Based on this, the number of various existing elements in the ideal or standard state will be explained based on the following assumptions.
The number of the plurality of charged particle beams 116 in the multi-beam 116 is N.
Correspondingly, the number of regions 126 on the surface of the sample 9 that are irradiated with the multi-beam 116 is also N.
The number of the plurality of detectors of the multi-detector 123, the number of the plurality of detection ranges 127 on the surface of the scintillator 122, and the number of the plurality of signals 141 from the plurality of detectors are also N.
The number of emitted electron beams 119 and the number of converged emitted electron beams 121 are also N. In FIG. 1, the emitted electron beams 119 are shown as one emitted electron beam for the sake of simplicity.

In the following description, a case where the destination (irradiation position) of the emitted electron beam 119 on the converging lens 120 changes as a result of the influence of crosstalk will be described as an example. That is, a case where the number of emitted electron beams 119 does not change even if crosstalk occurs will be described as an example. However, the present invention is not limited thereto. When considering the common point that each emitted electron is detected by an unintended detector, the present invention can be applied even when there are a plurality of emitted electron beams 119 from one region 126 due to the influence of crosstalk. Similarly, the present invention can be applied even when the thickness of one emitted electron beam 119 becomes unexpectedly large.

### [Multi-Beam Charged-Particle Microscope Apparatus]

FIG. 1 illustrates a configuration of a system in which the multi-beam charged-particle microscope apparatus 100 and the processor system 103 of Embodiment 1 are connected. The respective components of the system illustrated in FIG. 1 are electrically connected, and can communication and input/output with each other, for example.

The multi-beam charged-particle microscope apparatus 100 is particularly the scanning microscope apparatus 100. The scanning microscope apparatus 100 includes a charged particle imaging system 101 and the controller 102. The charged particle imaging system 101 includes a mechanism for generating the multi-beam 116 and irradiating the sample 9 with the multi-beam 116, and a mechanism for detecting emitted electrons from the sample 9. As these mechanisms, the charged particle imaging system 101 includes the charged particle beam irradiation system 104 and the detection system 125. The processor system 103 is connected to the controller 102.

The charged particle beam irradiation system 104 includes an electron gun 111, a collimator lens 113, a multi-beam forming element 115, a stage 118, and the like. The sample 9 is placed on the stage 118. The configuration, which is composed of the electron gun 111 and other components and in which the charged particle beam 116 which is the multi-beam 116 is formed through the multi-beam forming element 115, is described as the charged particle beam irradiation system 104.

The detection system 125 includes the converging lens 120, the imaging detector 131, the correction detector 132, and the like. The imaging detector 131 includes the scintillator 122 and the multi-detector 123. The correction detector 132 includes the scintillator 122 and the observation device 124.

The electron gun 111 generates an electron beam 112, which becomes a source of the multi-beam 116, and emits the electron beam 112 in the Z-axis direction (downward direction) as illustrated in the figure. In this example, one electron gun 111 is provided. The collimator lens 113 collimates the electron beam 112 emitted from the electron gun 111 into parallel light 114. The multi-beam forming element 115 converts the parallel light 114 into at least one or more charged particle beams 116 (corresponding to beamlets in the prior art). The multi-beam forming element 115 is, for example, a porous plate or an element including the plate. A plurality of charged particle beams 116 are formed by the multi-beam forming element 115. An example of the charged particles of the charged particle beam 116 is electrons.

In the example of Embodiment 1, for the multi-beam 116, a plurality (N) of emitted electron beams 119 are generated from the surface (X-Y plane) of the sample 9 irradiated with the multi-beam 116 including a plurality (N) of charged particle beams. Emitted electrons are particles such as secondary electrons (SE) and back-scattered electrons (BSE).

A drive control system (not illustrated) (including a drive circuit, and the like) is connected to each component of the charged particle beam irradiation system 104, and is driven and controlled by the controller 102.

The stage 118 is a sample stand for placing and holding the sample 9 to be imaged, and is a moving stage, and is a mechanism capable of moving in the horizontal direction (X-axis direction and Y-axis direction shown) or vertical direction (Z-axis direction), and rotating around a rotation axis. A stage drive control system (including a drive circuit, and the like) (not illustrated) is connected to the stage 118, and is driven and controlled by the controller 102.

Each charged particle beam 116 of the multi-beam 116 is emitted so as to scan, for example, each region 126 (FIG. 4 described later) on the surface of the sample 9.

The converging lens 120 converges the emitted electron beam 119 generated from the sample 9 irradiated with the multi-beam 116 toward the scintillator 122. The converged emitted electron beams 121 correspond to the plurality (N) of emitted electron beams 119, which correspond to the plurality (N) of charged particle beams 116, on one-to-one basis.

The components including and subsequent to the converging lens 120 configure the detection system 125. The scintillator 122 is a part of the imaging detector 131 and a part of the correction detector 132, and is a component used for both imaging and correction. The scintillator 122 is configured as one element common to the plurality of (N) detectors of the multi-detector 123 arranged at the subsequent stage. The scintillator 122 is a device that allows the emitted electron beam 121 that has been converged by the converging lens 120 to be incident thereon to emit light. The scintillator 122 is a device that converts the emitted electron beam 121 made incident on and collided with a surface thereof into photons. The scintillator 122 is a light emitting element that emits light at a collision position with each emitted electron beam 121 of the plurality of emitted electron beams 121 based on the multi-beam 116.

The scintillator 122 is used for detecting a signal of the emitted electron beam 121 based on the multi-beam 116 in a set with the multi-detector 123. The set of scintillator 122 and multi-detector 123 is also described as the imaging detector 131 (indicated by a broken line frame). The scintillator 122 is used for correction of crosstalk influence, specifically quantification of the crosstalk influence coefficient in a set with the observation device 124. That is, the scintillator 122 is used for both imaging and correction. The set of scintillator 122 and observation device 124 is also described as the correction detector 132 (indicated by a broken line frame).

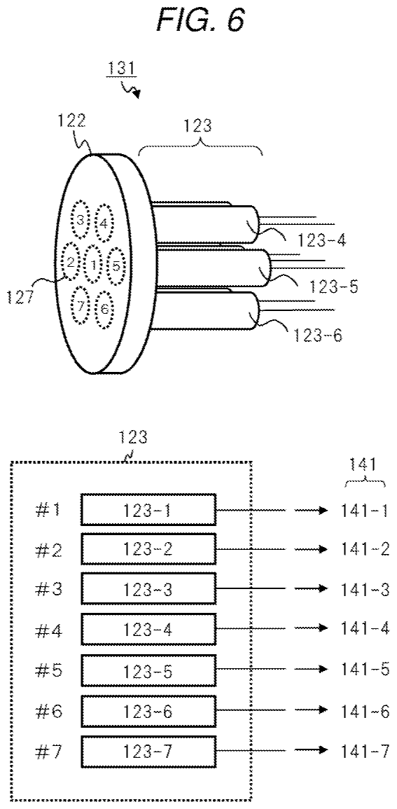

The multi-detector 123 includes a plurality (N) of detectors (detectors 123-1 to 123-7 in FIG. 6 described later), and each detector detects photons corresponding to the converged emitted electron beam 121 for each emitted electron beam 119 that reacted with the scintillator 122. The detector outputs the signal 141 (in other words, a detection signal, output signal, an image signal) corresponding to the detection of photons corresponding to each emitted electron beam 121. The signal 141 of the output of the multi-detector 123 is the plurality of detection signals from the plurality of detectors thereof.

The observation device 124 is a device that observes the state of light emission of the emitted electron beam 121 on the surface of the scintillator 122. The observation device 124 is, for example, an imaging element (for example, a CCD camera) that captures an image of the surface of the scintillator 122. The observation device 124 images the distribution of light amount of the plurality (N) of emitted electron beams s 121 on the incident surface of the scintillator 122. The observation device 124 outputs a signal 142 corresponding to the captured image (may be described as captured image for correction). The captured image for correction by the observation device 124 has information on a brightness value for each pixel (in other words, for each position coordinate).

The charged particle beam irradiation system 104 may have any configuration as long as it can irradiate the sample 9 with the multi-beam 116, and the detailed implementation is not limited. For example, the collimator lens 113 is not limited to one that collimates the electron beam 112 into parallel light 114. Further, in this example, the configuration including one electron gun 111 is adopted, but a configuration in which the multi-beam 116 is generated by a plurality of electron guns may be adopted.

Further, in the example of Embodiment 1, the charged particle beam irradiation system 104 is of a scanning type, and is configured to be able to irradiate the surface of the sample 9 with the plurality (N) of charged particle beams 116 as the multi-beam 116 so as to scan the surface of the sample 9. Although not illustrated, this scanning type charged particle beam irradiation system 104 includes a deflector and the like, and can realize scanning by changing the direction of irradiation of the multi-beam 116 by controlling the drive of the deflector and the like.

In the charged particle beam irradiation system 104, various deflectors (not illustrated) may be arranged on the trajectory of the charged particle beam from the electron gun 111 to the sample 9. Various types of deflectors include, for example, a scanning deflector, which is a deflector used for scanning the charged particle beam. Various configurations of the scanning deflector are possible and are not limited.

Each detector of the multi-detector 123 detects photons corresponding to emitted electrons incident on the detection range 127 (FIG. 5), which will be described later, as an analog signal that is an electrical signal. The signal 141 of the output of each detector is a signal generated based on the amount of photons corresponding to the detected emitted electrons. Each detector is configured with, for example, a photomultiplier (photomultiplier tube). Each photomultiplier generates a detection signal according to the amount of photons (for example, the number of photons per unit time) that have entered the own detection range 127. In the photomultiplier, photons made incident on the detection range 127 (in other words, entrance window) collide with a photocathode and are converted into electrons (in other words, photoelectrons), the electrons are amplified by being collided with a plurality of dynodes, and the amplified electrons are output from the electrodes as a signal current. The detector of the multi-detector 123 is not limited to the photomultiplier, and a silicon photomultiplier (SipM) or the like can also be applied therefor.

There are also no limitations on the detailed configurations of the scintillator 122, the multi-detector 123, and the observation device 124.

The controller 102 includes a processor 204, a memory 203, a detection circuit 201, an interface circuit 202, a communication interface 207, an input/output interface 208, and the like.

The signal 141 detected and output by the multi-detector 123 is input to the detection circuit 201 of the controller 102. The multi-detector 123 and the detection circuit 201 are connected to each other by a signal line. The detection circuit 201 includes an analog-to-digital conversion circuit and the like. The signal 141, which is an analog signal, is converted into a digital signal by the analog-to-digital conversion circuit of the detection circuit 201. The converted digital signal is temporarily stored in the memory 203 through the interface circuit 202.

On the other hand, in the observation device 124, the state of the emission distribution of the emitted electron beam 121 on the surface of the scintillator 122 is observed and imaged at the same timing and period as the detection and imaging on the side of the scintillator 122 and the multi-detector 123, and the signal 142 representing the emitted electron emission distribution 128 (FIG. 5) is output in correspondence with the signal 141. The signal 142 from the observation device 124 is input to the controller 102 through a signal line, is received by the interface circuit 202, and is temporarily stored in the memory 203 as a part of data 206.

The memory 203 stores an image generation program 205 and the like in advance. Further, the data 206 stored in the memory 203 includes data regarding the signal 141 output from the multi-detector 123 and data of the captured image for correction regarding the signal 142 output from the observation device 124.

The processor 204 performs image generation processing and the like as processing according to the image generation program 205 of the memory 203. With this configuration, the digital signal from the detection circuit 201 based on the signal 141 is converted into image data of the captured image and stored in the memory 203 as the part of the data 206. The signal 142 is converted into image data of the captured image for correction, and is stored in the memory 203 as the part of the data 206.

The processor 204 transmits data of the captured image based on the signal 141 and data of the captured image for correction based on the signal 142 as the data 206 stored in the memory 203 to the processor system 103 through processing by a transmission program and through the communication interface 207.

The processor system 103 includes the processor 302, the memory 303, a communication interface 301, an input/output interface 310, and the like. Respective components in the processor system 103 and the like are connected to each other through a bus or the like, and are supplied with power from a power source (not illustrated). An input device 311 and an output device 312 are externally connected to the input/output interface 310.

The processor 302 is a computing device that reads a program such as the correction program 304 stored in the memory 303 and executes processing corresponding to the program. The processor 302 may be configured with, for example, a CPU, MPU, GPU, or the like, may be configured using a dedicated circuit such as an FPGA, or may be configured with a semiconductor device with other types of computation functions, such as a quantum processor.

Data 143 transmitted from the controller 102 is received by the processor system 103 through the communication interface 301, and data 305 that is temporarily stored in the memory 303 as data 305 is data that includes a captured image before correction and a captured image for correction.

The processor 302 performs correction processing according to the correction program 304 of the memory 303. The correction program 304 is a computer program that causes the processor 302 to execute correction processing regarding crosstalk.

During the correction processing, the processor 302 first performs a process of calculating the crosstalk influence coefficient based on the captured image for correction of the data 305. Then, the processor 302 performs correction processing on the captured image before correction of the data 305 through a calculation formula using the crosstalk influence coefficient, thereby obtaining a corrected captured image. Correction processing subsequent to the performed correction processing is a process of correcting the signal amount between a plurality of image signals of the plurality of detectors corresponding to the plurality of detection ranges 127 so that, for example, the mixing rate approaches 0% and the residual rate approaches 100%. As a result, an image close to the ideal image with reduced crosstalk influence can be obtained as the corrected captured image.

The processor 302 stores the obtained corrected captured image in the memory 303 as data 306. Thereafter, the processor 302 can output the corrected captured image based on the data 306. For example, the processor 302 may display the corrected captured image on the screen of an externally connected output device 312, for example, a display device, through the input/output interface 310. A user using the processor system 103 can check the corrected captured image on the screen. The user can input instructions and settings to the processor system 103 by operating the input device 311 while viewing information including a graphical user interface (GUI) as output information of the output device 312.

For example, when a targeted captured image or a correction execution instruction is input based on the operation of the user on the screen, the processor system 103 may perform crosstalk influence correction on the targeted captured image. Alternatively, ON/OFF regarding crosstalk influence correction may be set in advance as a design of the processor system 103 or as a setting by the user. In the case of the ON setting, the processor system 103 may automatically execute the crosstalk influence correction.

The input device 311 may be, for example, a keyboard, mouse, touch panel, microphone, and the like. The output device 312 may be, for example, a touch panel, printer, speaker, and the like. There may be only one of the input device 311 and the output device 312. An input/output device may be built-in the processor system 103.

Further, the processor 302 may transmit data such as the corrected captured image to an external device through the communication interface 301. Examples of external devices include a database server, other types of inspection devices, a user client terminal device, and the like.

The processor system 103 may be configured with a computer such as a PC, a server computer, a tablet terminal, or a smartphone. The processor system 103 may be configured with a computer system including one or more of these computers. The server computer may be a server on a communication network, for example, a cloud server of a cloud computing system.

When the processor system 103 is configured as a server, the user may access the server from a client terminal device to utilize its function. In that case, the user's client terminal device is responsible for the functions of a user interface and screen display. The client terminal device transmits an instruction or the like to the server, and the server executes processing according to the instruction or the like, generates processing result information or screen data (data required for output to the user) including the processing result information, and transmits the data to the client terminal device. The screen data may be, for example, a web page, or may be data such as a program for outputting the processing result information on the client terminal device. The client terminal device can display the screen on the display device based on the received processing result information or screen data, and the user can check the processing result and the like by looking at the screen.

The processor system 103 includes one or more processors and one or more memory resources. Although FIG. 1 illustrates one processor 302 and one memory 303, the present invention is not limited thereto, and there may be a plurality of processors or a plurality of memories. The memory 303 is configured with, for example, a nonvolatile storage device or a volatile storage device. The memory 303 may be configured with a storage device such as a ROM or RAM, or a storage device such as a flash memory or SSD. The memory 303 may be configured as a storage region of an external storage device.

The program such as the correction program 304 may be stored in a non-transitory computer-readable storage medium, or may be stored in a program distribution server or the like on a communication network. The processor system 103 may read the program from the storage medium or the program distribution server and store the program in the memory 303 when necessary.

The image data stored in the memory 303 is composed of, for example, a file, and is managed by the processor 302 as a file in a file system, but is not limited thereto.

A system such as the processor system 103 is realized in cooperation with predetermined hardware and software. In Embodiment 1, the function of crosstalk influence correction is realized and implemented by program processing according to the correction program 304 by the processor 302, but is not limited thereto, and at least a part of the function may be realized by hardware such as an integrated circuit.

The controller 102 is also connected to an input device and an output device (not illustrated) through the input/output interface 208, and a person such as an operator using the charged-particle microscope apparatus 100 can input instructions and settings to the controller 102 through these input/output devices. The operator for the controller 102 and the user for the processor system 103 may be the same person. Further, those inputs and outputs to the controller 102 may be integrated as one input and output by the processor system 103.

### [Processing Flow of Processor System]

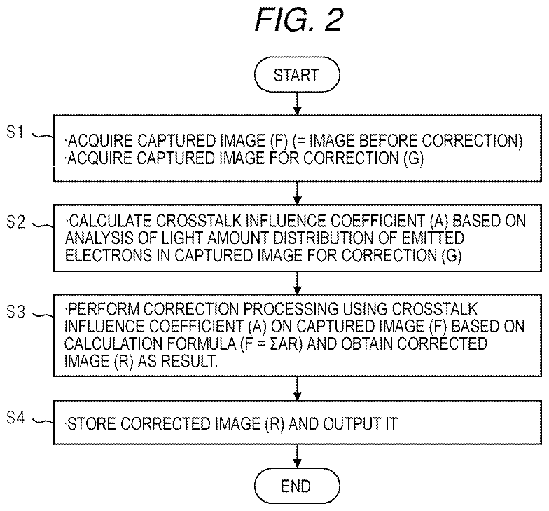

FIG. 2 illustrates a main processing flow in the processor system 103 of Embodiment 1, and includes steps S1 to S4. This flow is realized by the processor 302 described above executing processing according to the correction program 304.

In step S1, the processor system 103 acquires the data 143 including data of a captured image (denoted as F) based on the signal 141 of the output from the multi-detector 123 described above and data of the captured image for correction (denoted as G) based on the signal 142 of the output from the observation device 124 described above through communication from the controller 102 of the scanning type charged-particle microscope apparatus 100 in FIG. 1, and stores the data 143 as data 305 in the memory 303.

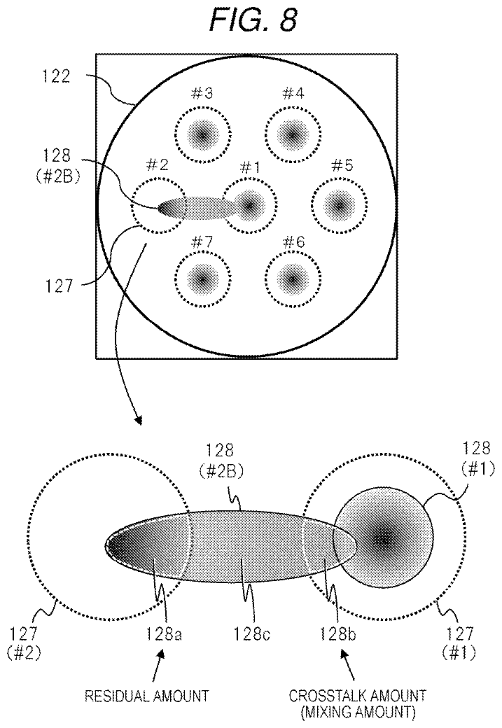

In step S2, the processor system 103 calculates a crosstalk influence coefficient (denoted as A) based on the analysis of the emitted electron emission distribution 128 (FIG. 5 or FIG. 8) in the captured image for correction G. Details thereof will be described later. The crosstalk influence coefficient (A) is a parameter representing the degree of the influence of crosstalk between a plurality of image regions corresponding to the plurality of detection ranges 127 on the surface of the scintillator 122, and is a parameter defined and used for crosstalk influence correction in Embodiment 1. Information on the calculated crosstalk influence coefficient (A) is also stored in the memory 303.

In step S3, the processor system 103 performs correction processing using the crosstalk influence coefficient (A) on the captured image (F) based on the calculation formula (F=CAR) described below, and as a result, a corrected image (denoted as R) is obtained. The corrected image (R) corresponds to the data 306 described above, and is an image with reduced crosstalk influence and an image close to the ideal image with reduced ghost image.

In step S4, the processor system 103 stores data 306 of corrected image (R) in the memory 303 and outputs the data 306 to the user.

### [Processing Sequence]

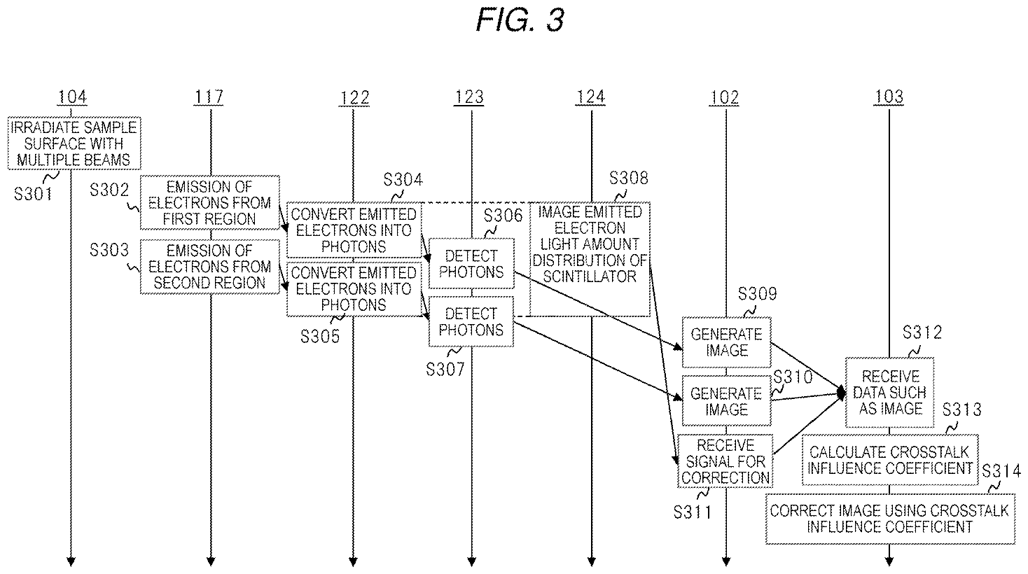

FIG. 3 illustrates a sequence of processing operations including crosstalk correction processing performed in the system of FIG. 1 and the sequence includes crosstalk amount calculation and image correction and includes steps S301 to S314.

First, in step S301, the imaging system 101 of the charged-particle microscope apparatus 100 generates the multi-beam 116 by the charged particle beam irradiation system 104 based on drive control by the controller 102, and irradiates a plurality of (N) regions 126 (FIG. 4) on the surface of the sample 9 while scanning the plurality of (N) charged particle beams 116.

Next, in steps S302 and S303, the emitted electron beams 119 are emitted from respective regions 126 on the surface of the sample 9, for example, a first region and a second region. In FIG. 3, for convenience of explanation, among the plurality (N) of charged particle beams 116, the plurality (N) of regions 126, and the like, two portions are particularly focused and described as the first region, the second region, and the like. The two portions are simple examples when considering the crosstalk influence, and correspond to the case when considering the crosstalk amount from the second detection range to the first detection range, and the like, which will be described later.

In steps S304 and S305, the emitted electron beams 119 from the respective regions 126 become the emitted electron beams 121 (for example, first emitted electron beam and second emitted electron beam) converged through the converging lens 120, and are imaged on respective detection ranges 127 (for example, first detection range and second detection range) on the surface of the scintillator 122 and converted into photons.

In steps S306 and S307, respective photons are detected by respective corresponding detectors (for example, first detector and second detector) of the multi-detector 123 as the signal 141 (for example, first signal and second signal).

Meanwhile, in step S308, by being matched with the detection timing and the imaging timing in the imaging detector 131, the observation device 124 of the correction detector 132 images the emitted electron light amount distribution 128 (FIG. 5 and the like) due to the collision of the emitted electron beam 121, which is generated when forming an image on the surface of the scintillator 122.

In steps S309 and S310, the controller 102 receives respective signals 141 from the multi-detector 123 and generates respective captured images, that is, respective images corresponding to each charged particle beam 116, each region 126, each detector, and the like, based on the signals 141.

In step S311, the controller 102 receives the signal 142 of the captured image for correction from the observation device 124.

In step S312, the processor system 103 receives data such as a transmitted image (captured image and captured image for correction) from the controller 102.

In step S313, the processor 302 first calculates crosstalk influence coefficient (mixing rate and the like) based on the analysis of the captured image for correction, by executing the correction processing according to the correction program 304. Then, in step S314, the processor 302 obtains a corrected image by correcting the image from the real image corresponding to the captured image so as to reduce the crosstalk influence, through a predetermined calculation formula, using the crosstalk influence coefficient obtained in step S313. Corrections to reduce the crosstalk influence include correction of the signal amount to bring the mixing rate closer to 0% and correction of the signal amount to bring the residual rate closer to 100% for each image signal corresponding to the detection range 127. The signal amount is brightness or the like.

With this configuration, as a plurality of images related to the plurality of charged particle beams 116, the plurality of regions 126, the plurality of detectors of the multi-detector 123, and the plurality of signals 141, images that are respectively close to ideal images with reduced crosstalk influence are obtained. After that, the processor system 103 displays the corrected image on a screen to the user, for example.

### [Sample Surface and Scintillator]

FIG. 4 is a schematic explanatory diagram illustrating irradiation (indicated by solid arrow) of a surface 9a of the sample 9 (for example, circular wafer) with a plurality (N) of charged particle beams 116 as the multi-beam 116, a plurality (N) of emitted electron beams 119 as the emitted electron beams 119 generated in response to the irradiation, and a state in which the emitted electron beams 119 converge to the surface of the scintillator 122 as the emitted electron beams 121 through the converging lens 120. FIG. 4 illustrates a schematic configuration when detecting the plurality of (N) emitted electron beams 119, which are generated from a group of regions 126 when the surface of the sample 9 is divided into the plurality of (N) regions 126 according to the plurality of (N) charged particle beams 116, on the surface of the scintillator 122. In this example, the plurality (N) is set to N=7, but is not limited thereto.

The plurality of (N) regions 126 are included in the surface 9a which is an upper surface of the sample 9. In this example, the region 126 is rectangular. As illustrated in the lower part of FIG. 4, each region 126 of the plurality of regions 126 is a region that is irradiated with each associated charged particle beam 116 while the charged particle beam 116 scans the region. The scanning is, for example, linear sequential scanning.

The emitted electron beams 119 emitted from respective regions 126 are indicated by dashed line arrows. The emitted electron beams 119 become the plurality (N) of emitted electron beams 121 converged through the converging lens 120, and the plurality (N) of emitted electron beams 121 are incident on the surface of the scintillator 122. In this example, the incident surface of the scintillator 122 is circular.

### [Scintillator and Detection Range]

FIG. 5 illustrates, when the incident surface is viewed from above, a plurality (N) of detection ranges 127 of the plurality (N) of detectors (see FIG. 6 below) of the multi-detector 123 on the incident surface of the scintillator 122 and the emitted electron light amount distribution 128 in image regions in the captured image for correction associated with those detection ranges 127. The image region in the captured image for correction is an image region when the detection range 127 is viewed in the captured image for correction.

FIG. 5 schematically illustrates, in an ideal state without crosstalk, an observation state of the emitted electron light amount distribution 128 in the captured image for correction by the observation device 124 at the timing when the emitted electron beam 121 generated from each region 126 of the sample 9 in FIG. 4 is detected in the detection range 127 of each detector of the multi-detector 123. In the ideal state, the light amount distribution 128 of each emitted electron beam 121 is aligned and fits within each detection range 127, as illustrated in the figure.

The large rectangle 500 in FIG. 5 indicates an example of an imaging range 500 of the captured image for correction when covering the entire surface of the scintillator 122. The emitted electron light amount distributions 128 are light amount distributions corresponding to respective emitted electron beams 119 and 121 based on respective charged particle beams 116. Each emitted electron light amount distribution 128 has a gradation of light amount. In the drawings, for convenience, the emitted electron light amount distribution 128 is schematically illustrated as an ellipse whose center is black and which becomes gray as it goes outward in the radial direction. The black represents a relatively bright or high light amount, and the gray represents a relatively dark or low light amount.

Further, the plurality (N) regions 126 in FIG. 4 and the plurality (N) detection ranges 127 in FIG. 5 correspond to each other by a number N, and are designed in advance so that one emitted electron light amount distribution 128 from one rectangular region 126 fits in one circular detection range 127 as an ellipse, depending on the dimensions and the configuration of the optical system. The ellipse of one light amount distribution 128 is a light amount distribution generated regarding a certain pixel within a certain region 126 at a certain scanning time point of a certain charged particle beam 116, as illustrated in FIG. 4. Since the charged particle beam 116 and the emitted electron beams 119 and 121 are formed as trajectories in three-dimensional space, the beams are imaged as ellipses in the detection range 127.

Further, for the purpose of explanation, in order to identify N (N=7) detection ranges 127, detectors, and the like, they are numbered #, for example, #1 to #7, as illustrated in the lower part of FIG. 5. For example, detection range #1 is located in the center of the surface of the scintillator 122, and detection range #2 is located on the left side of the detection range #1. Below, each detection range 127 and the like may be described as, for example, detection range #1 and the like using the number # as appropriate.

### [Scintillator and Multi-Detector]

FIG. 6 illustrates a perspective view of the general configuration of the scintillator 122 and the multi-detector 123 in the imaging detector 131 at the upper part, and illustrates functional blocks of the multi-detector 123 at the lower part thereof. In the upper perspective view of FIG. 6, among the multi-detectors 123, detectors 123-4, 123-5, and 123-6 corresponding to #4, #5, and #6 are visible. For example, photons of the emitted electron beam 121 that have entered the detection range 127 indicated by #5 are detected by the detector 123-5 and output as a signal 141-5.

Although not illustrated, an emission surface of the scintillator 122 and an incident surface of each detector may be spaced apart.

When the camera, which is the observation device 124 in FIG. 1, images the incident surface of the scintillator 122 as illustrated in FIG. 5, the signal 142 of captured image for correction having the same content as the imaging range 500 in FIG. 5 is obtained. In FIG. 1, the components are arranged so that an optical axis of imaging the observation device 124 is oblique to the surface of the scintillator 122. Although the image captured by the observation device 124 is not a plan view image, it is also possible to obtain a plan view image as illustrated in FIG. 5 by performing image processing on the captured image.

In the ideal state, for example, emitted electron beam #1 generated from region #1 of FIG. 4 is incident on detection range #1 of FIG. 5 and is detected by detector #1, which is a detector 123-1 of FIG. 6, and a signal 141-1, which is a detection signal, is output. Similarly, emitted electron beam #2 generated from region #2 of FIG. 4 is incident on detection range #2 of FIG. 5 and is detected by detector #2, which is a detector 123-2 in FIG. 6, and a signal 141-2, which is a detection signal, is output.

In the captured image for correction captured by the observation device 124 of the correction detector 132 by being matched with the detection timing and the imaging timing in the imaging detector 131, the emitted electron light amount distribution 128 similar to that in FIG. 5 is included. Further, within the captured image for correction, the plurality of detection ranges 127 are also included as corresponding image regions. Alternatively, even when the plurality of detection ranges 127 are not included as image regions in the captured image for correction, since the positions and shapes of the plurality of detection ranges 127 on the surface of the scintillator 122 are prescribed in advance, the positions and shapes of the plurality of detection ranges 127 within the captured image for correction can be known from the prescribed information.

That is, from the captured image for correction, the processor system 103 can know the relationship between the positions and shapes of the plurality of detection ranges 127 on the incident surface of the scintillator 122 and the positions and shapes of the plurality of emitted electron light amount distributions 128 regarding the plurality of emitted electron beams 121.

### [Occurrence of Crosstalk Due to Sample Charging]

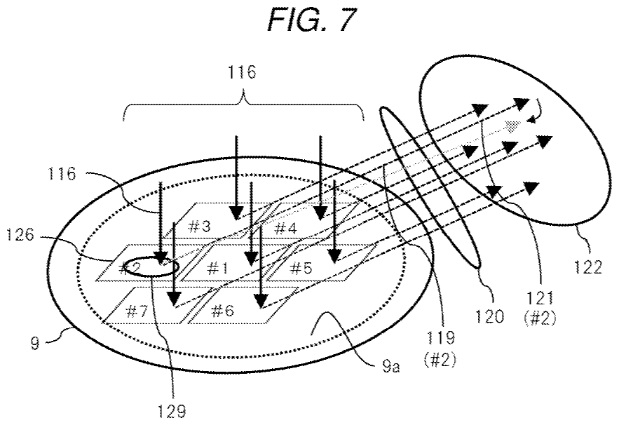

FIG. 7 is an explanatory diagram of the occurrence of crosstalk due to sample charging. FIG. 7 schematically illustrates, for example, a state in which a virtual lens 129 occurs due to charging in a part of the region 126, for example, region #2, on the surface of the sample 9 when the emitted electron beam 121 is generated in the ideal state as illustrated in FIG. 4 and FIG. 5. Due to the action of this virtual lens 129, the trajectories of the emitted electron beams 119 and 121 (#2) from this region #2 change, as illustrated by the gray dotted arrow, and the incident positions and shapes of the emitted electron beams 119 and 121 (#2) on the surface of the scintillator 122 change.

When charging occurs locally in a certain region #2, or the difference between a charging state in region #2 and a charging state in other regions becomes large, an electric field changes and the virtual lens 129 occurs in region #2. For the purpose of explanation, the virtual lens 129 refers to a change in the state of the trajectory of the emitted electron beams 119 and 121 from a local region due to a change in an electric field in the region on the sample 9 surface irradiated with the multi-beam 116.

Due to the virtual lens 129 in region #2, the emitted electron beams 119 and 121 (#2) generated from region #2 may deviate from the trajectory in the ideal state, deviate from detection range #2 (FIG. 5), and extend into the other detection range 127 (FIG. 8 described later) on the surface of the scintillator 122. Such a phenomenon corresponds to crosstalk.

In the example of FIG. 7, one virtual lens 129 occurs in accordance with exactly one region 126, but is not limited thereto, and the virtual lens 129 may occur in various ways on the surface of the sample 9. For example, the virtual lens 129 may occur at a position shifted from the region 126. A plurality of small-sized virtual lenses 129 may also occur within the region 126. A large-sized virtual lens 129 may also occur across a plurality of regions 126.

FIG. 8 illustrates an example of the emitted electron light amount distribution 128 on the surface of the scintillator 122 when the virtual lens 129 as illustrated in FIG. 7 has occurred. In this example, the light amount distribution of the emitted electron beam 121 (#2) incident on detection range #2 is the light amount distribution 128 (#2B), whereas the light amount distribution is the light amount distribution 128 (#2A) of FIG. 5 in the ideal state. The lower part of FIG. 8 illustrates only two portions of detection range #2 on the left and detection range #1 in the center, in an enlarged manner. In this example, the light amount distribution 128 (#2B) regarding the emitted electron beams 119 and 121 (#2) from region #2 of FIG. 7 becomes the light amount distribution 128 (#2B) that deviates from inside the detection range 127 (#2) on the left side to outside, especially to the right, and extends into the detection range 127 (#1) in the center.

The example of FIG. 8 illustrates a case where the emitted electron light amount distribution 128 between the detection ranges 127 is such that the emitted electron light amount distribution 128 (#2B) extends from detection range #2 on the left to detection range #1 in the center due to the influence of the virtual lens 129 in FIG. 7. The present invention is not limited thereto, and the emitted electron light amount distribution 128 between the detection ranges 127 may occur in various directions and the like depending on the state of the virtual lens 129.

By looking at the emitted electron light amount distribution 128 (#2B) in the captured image for correction as illustrated in FIG. 8, the processor system 103 can know that there is the crosstalk influence between regions #2 and #1. In addition, the processor system 103 can know a source and destination of the crosstalk influence of this light amount distribution 128 (#2B) from the brightness and shape of this emitted electron light amount distribution 128 (#2B). That is, the source is an outflow source, for example, the detection range 127 (#2) on the left side, and the destination is a mixing destination, for example, the detection range 127 (#1) in the center.

To explain in more detail, the emitted electron light amount distribution 128 (#2B) has a residual portion 128a that falls within detection range #2, a mixing portion 128b that is within another detection range #1, and an intermediate portion 128c that is outside detection range #2 but not within the other detection range #1. The emitted electron light amount distribution 128 (#2B) is the sum of the portion 128a, the portion 128b, and the portion 128c. The mixing portion 128b becomes a crosstalk component and an extra light amount for detection range #1. The residual portion 128a becomes a normal component for detection range #2. The portion 128c and the portion 128b are components that have flowed out of detection range #2. The residual portion 128a is obtained by subtracting the outflow portions 128c and 128b from the light amount distribution 128 (#2B).

In this case, in detection range #1, in addition to the light amount that is incident on detection range #1 from region #1, a part of the light amount (portion 128b) that should be incident on detection range #2 from region #2 is mixed. This mixing corresponds to crosstalk. Further, in detection range #2, a part of the light amount of the emitted electrons from region #2 flows out to the outside, and only a part (portion 128a) of the light amount remains and is detected.

The detection signal 141-1 of the detector 123-1 (FIG. 6), which is the first detector having detection range #1, becomes an image in which an extra light amount is mixed into and the brightness is increased compared to an image in the ideal state. The detection signal 141-2 of the detector 123-2, which is the second detector having detection range #2, becomes an image in which a part of the light amount has flowed out to the outside and the brightness is decreased compared to an image in an ideal state.

The example in FIG. 8 is an example of the emitted electron light amount distribution 128 and crosstalk between the two detection ranges 127 (#1 and #2), but the present invention is not limited thereto, and crosstalk may occur in various ways in each detection range 127. In the example of FIG. 8, the mixing portion 128b of light amount distribution #2B partially overlaps the light amount distribution #1 within the detection range #1, but there may be a case where the region of the mixing portion and the light amount distribution overlap each other in this way, and a case where they do not overlap each other.

For example, when considering the mixing rate from detection range #2 to detection range #1, the mixing rate, which will be described later, can be calculated as [mixing rate]=[crosstalk amount (mixing rate)]/[population parameter] by using the entire light amount distribution #2B as the population parameter and the portion 128b mixed into detection range #1 as the crosstalk amount (in other words, the mixing amount). Similarly, the mixing rate can be calculated for each detection range 127.

In addition, for example, when considering the residual rate in detection range #2, if the entire light amount distribution #2B is used as a population parameter, the portion 128a remaining in detection range #2 is used as a residual amount, and the portions 128c and 128b that has flowed out to the outside detection range #2 are used as outflow amounts, the residual rate, which will be described later, can be calculated as [residual rate]=[residual amount]/[population parameter]=([population parameter]−[outflow amount])/[population parameter]. Similarly, the residual rate can be calculated for each detection range 127.

By integrating calculations that take into account the mixing rate and residual rate as described above for all the plurality (N) detection ranges 127, the crosstalk influence coefficients for the detectors of the respective detection ranges 127 can be calculated.

As in the example at the lower part of FIG. 8, even when a plurality of emitted electron light amount distributions 128 from different origins partially overlap within a certain detection range 127 (for example, #1), it is possible to grasp the overlap to some extent based on image processing of the captured image for correction, such as the analysis of brightness and shape. Therefore, even in that case, it is possible to quantify the crosstalk influence.

As illustrated in FIG. 5, when there is no crosstalk, the first emitted electron beam emitted from the first region (region 126) with which the first charged particle beam collides is incident on and imaged in the first detection range (detection range 127) of the first detector and detected as a first signal (signal 141). The situation at that time can be observed, in the captured image for correction, as a first light amount distribution corresponding to the first emitted electron beam in the first image region corresponding to the first detection range. The same applies to other detections, for example, the second charged particle beam, the second region, the second emitted electron beam, the second detector, the second detection range, the second image region, and the second signal.

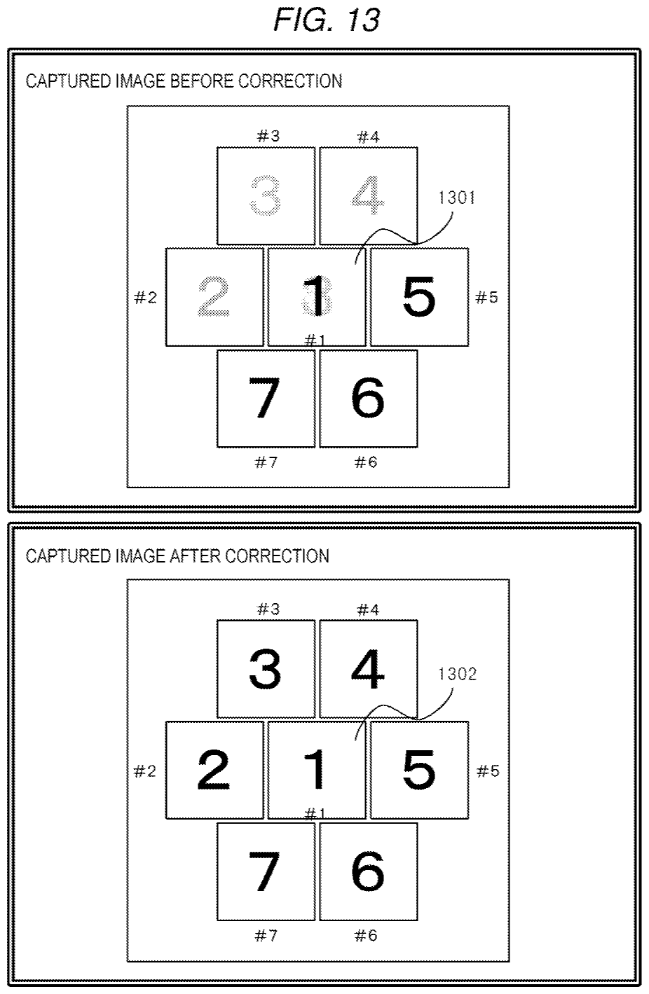

As a crosstalk phenomenon, for example, as illustrated in FIG. 8, when the first emitted electron beam emitted from the first region with which the first charged particle beam collides is incident on and imaged in the first detection range of the first detector and is imaged and detected as the first signal, the second emitted electron beam emitted from the second region with which the second charged particle beam collides may be mixed into the first detection range due to a change in trajectory. In the case of such a crosstalk phenomenon, when looking at the first image of the first signal of the first detector, the content in which the brightness increases due to mixing of light from outside and the content in which some signals are superimposed appear. When looking at the second image of the second signal of the second detector, the content in which the brightness decreases due to the outflow of light to the outside and the content in which some signals are missing appear. In other words, in the first image of the first signal, the image content that should be captured in the second image of the second signal may appear to be superimposed as a ghost image (FIG. 13 described later).

The processor system 103 quantifies the crosstalk influence between the detection ranges 127 using the captured image for correction regarding the crosstalk phenomenon related to the detection of the emitted electron beam 121 based on the multi-beam 116 as described above. For example, the processor system 103 specifies the crosstalk amount from the second detection range to the first detection range. The processor system 103 corrects the image based on the signal 141 of the output of the multi-detector 123 based on the crosstalk amount to obtain an image with reduced crosstalk influence.

### [Plurality of Crosstalk Influences]

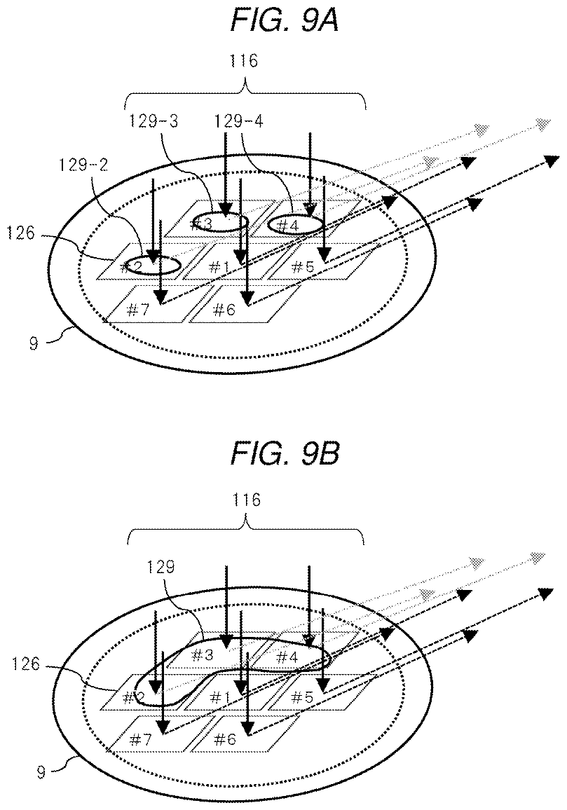

FIGS. 9A and 9B illustrate other examples of the occurrence of the virtual lens 129 due to sample charging in FIGS. 9A and 9B. FIG. 9A illustrates a case where the virtual lenses 129 (129-2, 129-3, and 129-4) occur in regions #2, #3, and #4 of the surface 9a of the sample 9, respectively. FIG. 9B illustrates a case where a large virtual lens 129 occurs across regions #2, #3, and #4. The details of the virtual lens 129, such as the illustrated example, may not be known during crosstalk influence correction.

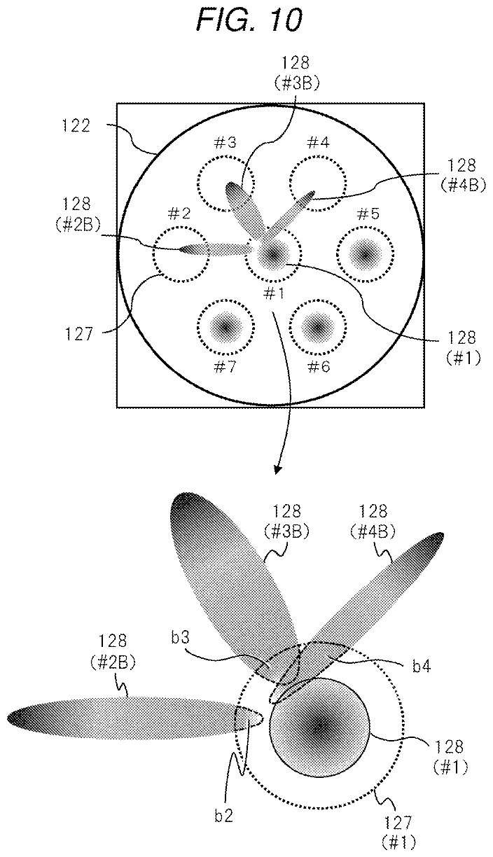

FIG. 10 further illustrates a case where the crosstalk influence occurs between the plurality of detection ranges 127 regarding the plurality of emitted electron beams 119 and 121 from the plurality of regions 126 on the surface of the scintillator 122. This example illustrates a case where three types of mixing from detection range #2, mixing from detection range #3, and mixing from detection range #4 as crosstalk in another detection range 127 (second detection range in explanation) when specifying and calculating the crosstalk amount regarding detection range #1 by focusing attention on detection range #1 as an own detection range (first detection range in explanation). As the factor of the occurrence of crosstalk, a case in which the virtual lenses 129 due to charging occur in regions #2, #3, and #4 in FIGS. 9A and 9B can be considered.

In the lower part of FIG. 10, the emitted electron light amount distribution 128 within detection range #1 is illustrated in an enlarged manner. Within detection range #1, first, an emitted electron light amount distribution 128 (#1) due to the emitted electron beams 119 and 121 (#1) from region #1 is included. Further, within detection range #1, a part of the light amount distribution 128 (#2B) of emitted electron beam #2 from region #2 is included as a mixing portion b2. Further, within detection range #1, a part of the light amount distribution 128 (#3B) of emitted electron beam #3 from region #3 is included as a mixing portion b3. Further, within detection range #1, a part of the light amount distribution 128 (#4B) of emitted electron beam #4 from region #4 is included as a mixing portion b4. These three mixing portions b2, b3, and b4 become components of crosstalk from outside for detection range #1.

In FIG. 10, due to the action of the virtual lens 129 of FIGS. 9A and 9B, a plurality of (for example, three) emitted electron light amount distributions 128 (#2, #3, and #4) deviate from inside the detection ranges 127 (#2, #3, and #4) in an ideal state and extend into another detection range 127, for example, detection range #1. As a result, a plurality of emitted electron light amount distributions 128 (#1, b2, b3, and b4) coexist within detection range #1. The image based on the signal 141-1 of the detector 123-1 having detection range #1 becomes an image formed by including components (b2, b3, and b4) of light amounts mixed in from other sources in emitted electron light amount distribution #1 that should originally be detected. As a result, an image based on the signal 141-1, especially an image formed by scanning the region 126 (#1) becomes an image in which images from other regions 126 (#2, #3, and #4) are mixed as ghost images in the image that shows the structure of region 126 (#1) as the original image.

In Embodiment 1, the state of the plurality of emitted electron light amount distributions 128 for the plurality of detection ranges 127 on the surface of the scintillator 122 as described above is quantified as a captured image for correction by imaging and image recognition by the observation device 124. The processor system 103 quantifies the crosstalk influence between the emitted electron light amount distributions 128 in the detection range 127 as a crosstalk influence coefficient such as the mixing rate, based on the captured image for correction.

In this example, regarding detection range #1 of FIG. 10, as the crosstalk influence, there is an amount of crosstalk exerted by three light amount distributions from outside, such as light amount distribution #2, light amount distribution #3, and light amount distribution #4. The processor system 103 calculates such a crosstalk amount as the crosstalk influence coefficient based on the analysis of the captured image for correction from the observation device 124 during calculation in step S2 described above.

The processor system 103 calculates the light amount of the emitted electron light amount distribution 128 included in each detection range 127 from the content of the captured image for correction as illustrated in FIG. 10, for example. This light amount can be calculated based on the brightness value of the captured image for correction. This light amount is an amount corresponding to the amount of electrons or the amount of photons detected by the detector of the multi-detector 123. The processor system 103 may calculate such a detected amount of electrons or detected amount of photons.

Further, the processor system 103 analyzes the position, shape, outline, area, brightness, direction of a change in brightness, direction in which the distribution extends (source and destination), and the like of each emitted electron light amount distribution 128 with respect to each detection range 127 from the content of the captured image for correction as illustrated in FIG. 10, for example. Consequently, it is possible to know from which detection range 127 (corresponding charged particle beam 116 and emitted electron beam 119, and the like) to which detection range 127 the crosstalk is occurring and how much crosstalk there is. Specifically, for each detection range 127, the mixing rate, the residual rate, and the like, which will be described later, can be calculated.

In addition, in the example of FIG. 10, regarding detection ranges #5, #6, and #7, the light amount distributions 128 respectively fall within the ideal detection ranges 127, and there is no crosstalk with other detection ranges 127. These portions can be treated as having a residual rate of 100% and a mixing rate of 0%.

### [Calculation of Crosstalk Influence Coefficient]

The calculation of the crosstalk influence coefficient is described. In the plurality of detection ranges 127 on the surface of the scintillator 122, for each detection range 127, it is possible to consider the crosstalk influence of mixing of the light amount from other detection ranges 127 (corresponding emitted electron beam 121) to own detection range 127 and the crosstalk influence of outflow of the light amount from the own detection range 127 (corresponding emitted electron beam 121) to other detection ranges 127. In the example of Embodiment 1, such crosstalk influence is calculated as a mixing rate and a residual rate.

The processor system 103 calculates the crosstalk influence between all seven detection ranges 127 as illustrated in FIG. 10, for example. In the example of FIG. 10, the mixing and outflow of the respective light amounts are calculated between light amount distribution #1 in detection range #1, light amount distribution #2B in detection range #2, light amount distribution #3B in detection range #3, and light amount distribution #4B in detection range #4.

When focusing attention on a certain detection range 127, setting an own detection range as the first detection range, and setting another detection range 127 other than the own detection range as the second detection range, the mixing rate from the second detection range to the first detection range can be calculated, and the residual rate within the first detection range due to outflow from the first detection range to the outside (including the second detection range) can be calculated.

In the example in FIG. 10, when focusing attention on light amount distribution #1 in detection range #1, it is possible to calculate the mixing rate from three light amount distributions #2B, #3B, and #4B of detection ranges #2, #3, and #4 to light amount distribution #1 of detection range #1. The mixing rate from detection ranges #5, #6, and #7 is 0%. The residual rate regarding the light amount distribution #1 in detection range #1 is 100% because there is no outflow to the outside. By integrating the mixing rate and the residual rate, the crosstalk amount in detection range #1 can be specified.

Similarly, when focusing attention on light amount distribution #2B of detection range #2, the mixing rate from the other detection range 127 is 0%, and the residual rate can be calculated using the residual portion 128a as illustrated in FIG. 8. The same applies to detection ranges #3 and #4. Regarding detection ranges #5, #6, and #7, the mixing rate is 0% and the residual rate is 100%.

A value representing the crosstalk influence is defined as a crosstalk influence coefficient. In Embodiment 1, as an example, the crosstalk influence coefficient uses the mixing rate and the residual rate. The mixing rate is a ratio of a light amount mixed as a crosstalk amount from another second detection range to a first detection range of interest. The residual rate is a ratio of a light amount that remains within the first detection range of interest excluding a light amount that flows out to the outside. A similar calculation is performed for each of all detection ranges.

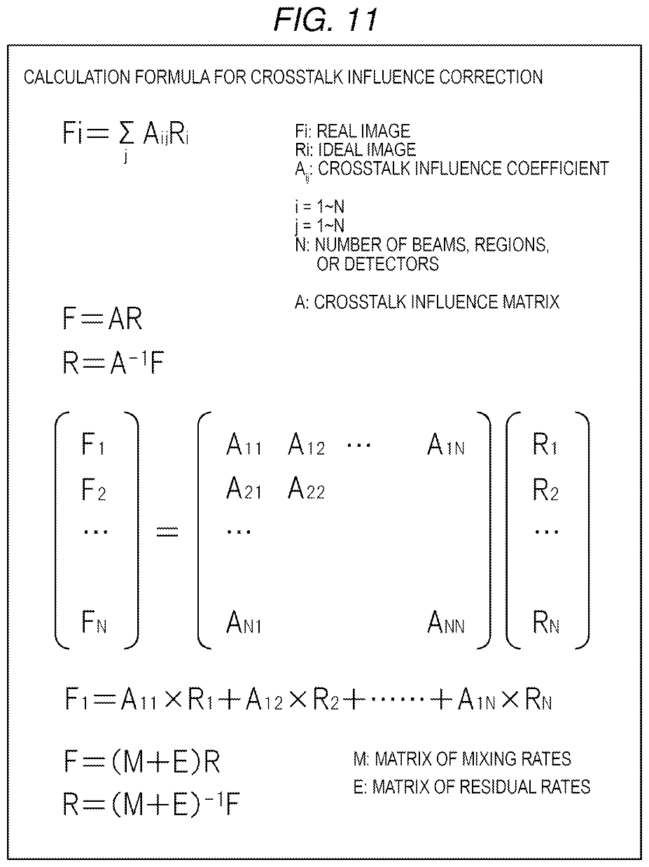

FIG. 11 illustrates a calculation formula for obtaining an ideal image by correction from a real image using a crosstalk influence coefficient, as a calculation formula for crosstalk influence correction. By generalizing the calculation based on the concept described above, the calculation formula can be defined as F₁=ΣAᵢⱼRᵢ. F₁ is an image as a real image (corresponds to the captured image in FIG. 2, that is, the image before correction) obtained by each detector of the multi-detector 123 when there is crosstalk. Rᵢ is an image as an ideal image (corresponds to the corrected image in FIG. 2) obtained by each detector of the multi-detector 123 in an ideal state where there is no crosstalk. The subscript i and the subscript j indicate a certain region 126, a detector in a certain detection range 127, a certain detection signal 141, and the like. i=1 to N and j=1 to N. For example, N=7.

Aᵢⱼ is the crosstalk influence coefficient. The crosstalk influence coefficient Aᵢⱼ is a value representing the crosstalk influence from another detection range j (corresponding emission electron light amount distribution 128) to a certain detection range i (first detection range), for example, when considering the relationship between the certain detection range i and the other detection range j (second detection range). ΣAᵢⱼ is the integration of the crosstalk influence from all other detection ranges j to detection range i. E denotes the summation over j.

The above calculation formula: F₁=ΣAᵢⱼRᵢ represents that the real image (F), which is detected by the detector on the basis of the emitted electron beam 121 from the region 126 based on a certain charged particle beam 116, is the result of the crosstalk influence being reflected on the ideal image (R).

The above calculation formula: F₁=EAᵢⱼRᵢ can be expressed as a determinant: F=AR as illustrated in the figure. In that case, the crosstalk influence coefficient Aᵢⱼ is a crosstalk influence matrix A.

In the correction of crosstalk influence, the ideal image (R) may be obtained based on the above calculation formula: F₁=ΣAᵢⱼRᵢ or the determinant: F=AR. The ideal image (R) is obtained as a solution from the simultaneous equation obtained by transforming F₁=ΣAᵢⱼRᵢ. The determinant: F=AR is transformed to R=A⁻¹F, and from this determinant, the ideal image (R) is obtained as a solution. For example, by substituting an inverse matrix A⁻¹ of the crosstalk influence matrix A and the real image (F), which is the captured image of the detector, into the determinant: R=A⁻¹F, the ideal image (R) is obtained.

Assume that 20% of the emitted electron light amount distribution #2B is mixed into region #1 as a crosstalk influence from region #2 to region #1, as in the examples in FIGS. 7 and 8. In this case, the determinant is, for example, F₁=A₁₁×R₁+A₁₂×R₂+ . . . +A_{1N}×R_{N} for region #1 and detection range #1. In the crosstalk influence matrix A, A₁₁ is the ratio of the light amount remaining in detection range #1, and A₁₂ is the ratio of the light amount distribution from the detection range #2 mixed into the detection range #1. A diagonal component in the crosstalk influence matrix A is the ratio of the component in which the light amount distribution 128 remains within the detection range 127. Components other than the diagonal component in the crosstalk influence matrix A are the ratio of the light amount distribution 128 from the detection range j mixed into the detection range i. The values of off-diagonal components (A₁₂ and the like) of the crosstalk influence matrix A are less than 1.

The crosstalk influence matrix A can be divided into a matrix of mixing rates (denoted as M) and a matrix of residual rates (denoted as E). In that case, A=(M+E). The determinant is F=(M+E)R, and R=(M+E)⁻¹F. In the matrix M of the mixing rates, if the component is mᵢⱼ, mᵢⱼ is a mixing ratio of the light amount distribution 128 from the detection range j to the detection range i (mixing portion 128b of the population parameter of #2B in FIG. 8), and the diagonal component is 0. In the residual rate matrix E, the off-diagonal components are 0. If the diagonal component is en, en is the residual ratio of the light amount distribution 128 within the detection range i, and is the ratio of the component obtained by subtracting the component that has flowed out of detection range i (residual portion 128a of the population parameter of #2B in FIG. 8).

Crosstalk influence correction in image units for each charged particle beam 116, each region 126, and each detector can be realized, for example, by the calculation formula using the crosstalk influence coefficient A as described above.

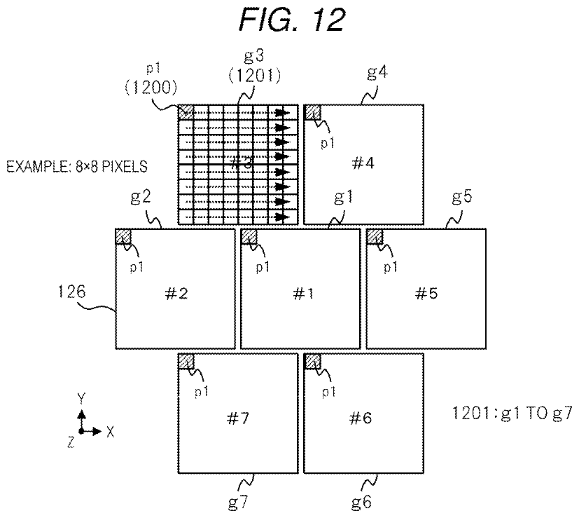

When focusing attention on pixel units in the image (for example, pixel p1 or the like in FIG. 12 described later) for each region 126, a pixel of the real image (F) (in other words, image in pixel units or pixel image) can be expressed as F₁ (x, y), and a pixel in the ideal image (R) (in other words, an ideal image in pixel units) can be expressed as Rᵢ (x, y). F₁ (x, y) corresponds to the brightness of the pixel located at the position coordinates (x, y) of the image created from the output signal 141 of an i-th detector among the plurality (N) of detectors. (x, y) are position coordinates within a two-dimensional image. For such an image in pixel units, crosstalk influence correction can be similarly realized by using the calculation formula described above (Modification 1 described later).

### [Image by Scanning]

A supplementary description will be given regarding images obtained by scanning in the case of the scanning type charged-particle microscope apparatus 100. The controller 102 adds scanning information (for example, scan pattern such as linear sequential scanning) regarding the multi-beam 116 to the signal 141 of the output of each detector of multi-detector 123, and generates a two-dimensional image for each region 126 on the surface of the sample 9, in other words, for each detector. The plurality of (N) generated images correspond to the real image F in the formula F=CAR described above.

FIG. 12 illustrates a plurality of (N=7) images 1201 (g1 to g7) corresponding to the plurality of (N=7) regions 126 (#1 to #7) of FIG. 4. For each region 126, one image 1201 is obtained through the signal 141 of one detector. For example, the image g3 is obtained from region #3. In the example of FIG. 12, one region 126 has 8×8 pixels in the X- and Y-directions. FIG. 12 illustrates a case where linear sequential scanning is performed by the charged particle beam 116 for each region 126. At a certain scanning time point, one pixel 1200 (for example, pixel p1 at the same position) in each region 126 is irradiated with the charged particle beam 116. For example, at a first scanning time point, the pixel p1 in the upper left corner of each region 126 is irradiated with each charged particle beam 116. Each region 126 is subjected to, for example, linear sequential scanning by the charged particle beam 116, and an image signal (in other words, pixel image) is obtained for each pixel 1200 regarding a plurality of pixels 1200.

The image of one pixel 1200 in each region 126 at a certain scanning time point as illustrated in FIG. 12 is obtained through the plurality of signals 141 from the plurality of detectors of the multi-detector 123, as illustrated in FIG. 4 or 5. For example, the emitted electron beams 119 and 121 from one region 126 (for example, 8×8 pixels) corresponding to the scanning of one charged particle beam 116 are imaged to be included within the detection range 127 (FIG. 5) of one detector. The controller 102 obtains a plurality of images 1201 (g1 to g7) of the plurality of regions 126 (N=7) as illustrated in FIG. 12 as the image 1201 for each region 126 by combining image signals of the plurality (for example, 8×8) of pixels 1200 at a plurality of time-series scanning time points.

The correction of the crosstalk influence in image units in Embodiment 1 is, for example, correction of the crosstalk influence between the images 1201 (g1 to g7) as illustrated in FIG. 12. The correction of crosstalk influence in pixel units in Modification 1, which will be described later, is correction of crosstalk influence between the pixels 1200, for example. In the case of correction in image units, a period of imaging by the observation device 124 is set to a period matching a period of imaging of the image 1201. In the case of correction in pixel units in Modification 1, the period of imaging by the observation device 124 is set to a period matching a period of imaging of the pixel 1200.

In the case of the scanning type charged-particle microscope apparatus 100, the same image region may be repeatedly scanned a plurality of times. In this case, the period of imaging by the observation device 124 in the correction in image units is set to a period matching a period in which such multiple scans of the same image region are combined into one scan.

### [Screen Display Example]

FIG. 13 illustrates an example in which the processor system 103 displays images before and after correction on the screen. An example of displaying an image before correction is illustrated at the upper part of FIG. 13, and an example of displaying a corrected image is illustrated at the lower part thereof. As an example, numbers representing the respective regions are formed in regions 126 (#1 to #7) on the surface of the sample 9. The image before correction is a captured image generated based on the detection signal 141 when there is crosstalk influence as illustrated in FIG. 10 described above, for example. In the case of this image, the light amount from detection ranges #2, #3, and #4 corresponding to regions #2, #3, and #4 is mixed into detection range #1 corresponding to region #1. Therefore, in an image 1301 corresponding to region #1, ghost images numbered 2, 3, and 4 are superimposed thereon. Further, in the images corresponding to regions #2, #3, and #4, there is respective outflow of light amount in regions #2, #3, and #4, and thus the brightness of images having numbers 2, 3, and 4 becomes low. In the corrected image, for example, in an image 1302 corresponding to region #1, the crosstalk influence from regions #2, #3, and #4 is reduced, and the image having number 1 is clearly captured.

The processor system 103 may display the image before correction on the screen, and when the user presses a correction button, the processor system 103 may execute correction processing and display the image after correction. Alternatively, the processor system 103 may display the images before and after correction side by side on the screen. Further, the processor system 103 may display the captured image for correction by the observation device 124 on the screen.

### [Effects and the Like of Embodiment 1]

According to Embodiment 1, the following effects can be obtained. In the multi-beam charged-particle microscope apparatus 100, crosstalk may occur during detection and imaging by the multi-detector 123 of the imaging detector 131 due to changes in the trajectory of the emitted electron beam 119 based on the multi-beam 116 due to factors such as sample charging and insufficient optical adjustment. For example, a situation in which a part of the light amount of emitted electrons that should be incident on the second detection range may be mixed into the first detection range (FIG. 8). In contrast, according to the processor system of Embodiment 1, the crosstalk influence can be reduced by correcting the captured image obtained from the controller 102. That is, an image close to the ideal image with reduced crosstalk influence can be obtained. According to Embodiment 1, even if the factors of crosstalk occurrence inside the charged-particle microscope apparatus 100 are unknown, for example, even if there is temporal or local sample charging that is difficult to grasp in advance, it is possible to correct the crosstalk influence on the captured image of the output of the charged-particle microscope apparatus 100.

### <Modification>

At least the following are possible as modifications to Embodiment 1.

### [Modification 1]

In Embodiment 1, correction of the crosstalk influence, for example, calculation of the crosstalk influence coefficient, is performed in image units of the image obtained for each charged particle beam 116, each region 126, and each detector. However, the present invention is not limited thereto, and in the modification, the crosstalk influence may be corrected, for example, the crosstalk influence coefficient may be calculated in pixel units of the pixel of the image. In this modification, crosstalk influence coefficients are calculated in respective pixel units, that is, between pixels, and each coefficient may have a different value. Crosstalk influence is reduced between images of respective pixel units.

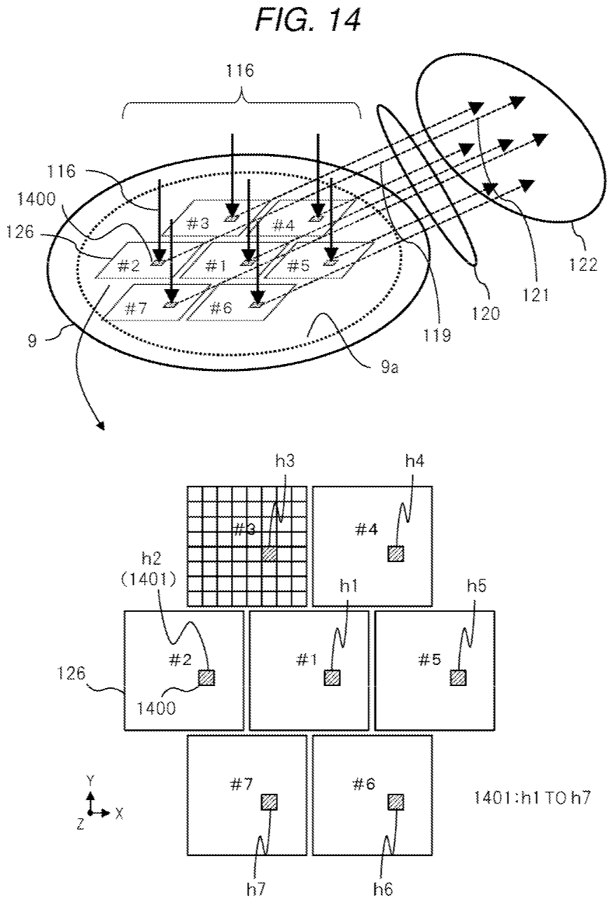

FIG. 14 illustrates an explanatory diagram of a concept regarding crosstalk influence correction in pixel units in Modification 1. The upper part of FIG. 14 illustrates the irradiation of a plurality of pixels 1400 on the surface of the sample 9 with the multi-beam 116, and the generation of a plurality of emitted electron beams 119 from the plurality of pixels 1400. The lower part of FIG. 14 illustrates an arrangement example of the plurality of pixels 1400 in the plurality of regions 126 and a plurality of pixel images 1401 obtained corresponding to the plurality of pixels 1400. Each pixel 1400 of the plurality of pixels 1400 is a pixel included in each of the regions 126 described above (for example, pixel at the same position within region 126), and the pixel images 1401 (for example, h1 to h7) are obtained as image signals (signal 141) each of which corresponds to each pixel. Although not illustrated, the emitted electron light amount distribution on the surface of the scintillator 122 has the same concept as in FIG. 5 and the like.

The crosstalk influence correction in pixel units in Modification 1 is the correction of the crosstalk influence between these pixels 1400, between the plurality of corresponding detectors, between the plurality of signals 141, and between the plurality of pixel images 1401. The imaging period for the captured image for correction of the observation device 124 is a period corresponding to the period during which the pixel 1400 is detected by the detector.

According to Modification 1, detailed crosstalk influence correction can be performed in pixel units. As another modification, crosstalk influence correction may be similarly performed with pixel blocks (for example, 2×2 pixel block, 4×4 pixel block, and the like) consisting of a plurality of pixels as units. As another modification, it is also possible to evaluate the crosstalk influence in pixel units first, then calculate statistics of the evaluation results (for example, temporary crosstalk influence coefficient), for example, an average value, in image units of the region 126, calculate a crosstalk influence coefficient in image units of the region 126 from the statistics, and perform crosstalk influence correction in image units of the region 126 using the crosstalk influence coefficient.

### [Modification 2]

In Embodiment 1, the processor system 103 evaluates the actual mixing rate and the like based on the actual emitted electron light amount distribution 128 in the captured image for correction and calculates the crosstalk influence coefficient. In calculating the crosstalk influence coefficient (step S2 in FIG. 2), the processor system 103 may further calculate the crosstalk influence coefficient by considering information such as the material, pattern shape, and imaging conditions (for example, parameter value of optical system, acceleration voltage of primary electron beam, scanning method and time, and the like) of the sample 9 to be imaged by the charged-particle microscope apparatus 100. For example, a charging state of the sample that causes crosstalk changes depending on the pattern shape and the like of the surface of the sample 9, and the charging state can be reflected in the details of crosstalk.

The processor system 103 in Modification 2 acquires not only data 143 of the captured image (FIG. 1) but also related information such as sample information and imaging condition information from the controller 102, and calculates the crosstalk influence coefficient in step S2 of FIG. 2 based on the correction program 304. One example of calculation is to estimate that the greater the degree of unevenness on the surface of the sample 9, the greater the charged amount based on the pattern shape information and to increase the crosstalk influence coefficient related to the uneven portion. According to Modification 2, it is possible to perform correction with higher accuracy by taking into account the factors that cause crosstalk to occur.

### [Modification 3]

In Embodiment 1, based on the data 143 of captured image (FIG. 1) generated by the controller 102, the processor system 103 corrects the captured image. The present invention is not limited thereto, and in Modification 3, the processor system 103 may acquire and receive the detection signal 141 of the multi-detector 123, and generate a captured image based on the detection signal 141 while performing correction using the crosstalk influence coefficient. In this Modification 3, the controller 102 transmits the detection signal 141, the signal 142 of the captured image for correction, scanning information related to detection, and the like, as data 143, to the processor system 103. The processor system 103 performs the process of generating a captured image while correcting the crosstalk influence, based on the data 143, in the same manner as in Embodiment 1.

### [Additional Remark]

In Embodiment 1, as illustrated in FIG. 1, the processor system 103 and the charged-particle microscope apparatus 100 are configured as separate hardware. The present invention is not limited thereto, and a configuration in which the processor system 103 is included in the charged-particle microscope apparatus 100, for example, a configuration in which the controller 102 and the processor system 103 are common may be adopted.

In the explanation so far, the charged particles of the charged particle beam 116 are electrons, but other charged particles such as ions may be used. In this case, the electron gun 111 can be read as a charged particle source 111 that generates charged particles, such as an electron gun or an ion gun that generates charged particles.

In the explanation so far, an example in which there is one electron gun 111 and a plurality of charged particle beams 116 are formed by the multi-beam forming element 115 has been exemplified, but the present invention may have other configurations as long as a plurality of charged particle beams 116 can be generated. For example, each electron gun 111 corresponding to each charged particle beam 116 may be provided (that is, a plurality of electron guns 111 may be provided).

Although the embodiments of the present disclosure have been specifically described above, the present disclosure is not limited to the embodiments described above, and various changes can be made thereto without departing from the gist. In each embodiment, addition, deletion, replacement, and the like of components except for essential components are possible. Unless specifically limited, each component may be singular or plural. A form that combines each embodiment and modification is also possible.

What is claimed is:

1. A processor system that is able to communicate with a charged-particle microscope apparatus, the system comprising:
the charged-particle microscope apparatus includes
a charged particle beam irradiation system that includes at least one charged particle source, and irradiates a first region on a sample surface with a first charged particle beam generated using the charged particle source while irradiating a second region on the sample surface with a second charged particle beam generated using the charged particle source,
a detection system including
a correction detector that detects a first emitted electron emitted from the first region and a second emitted electron emitted from the second region,
a first detector that detects the first emitted electron through a part of the correction detector and outputs a first signal, and
a second detector that detects the second emitted electron through a part of the correction detector and outputs a second signal, and
a controller that generates a first brightness of a first pixel corresponding to a first position within the first region based on the first signal and generates a second brightness of a second pixel corresponding to a second position within the second region based on the second signal, wherein
the processor system includes one or more memory resources and one or more processors, and
the processor
(A) stores the first brightness and an output of the correction detector acquired from the charged-particle microscope apparatus in the memory resource,
(B) specifies a first crosstalk amount from the second emitted electron to the first signal, regarding the amount detected by the first detector, based on the output of the correction detector, and
(C) corrects the first brightness based on the first crosstalk amount.

2. The processor system according to claim 1, wherein
the controller generates a first image including the first pixel as generation of the first brightness of the first pixel, and generates a second image including the second pixel as generation of the second brightness of the second pixel.

3. The processor system according to claim 1, wherein
the correction detector includes
a light emitting element that emits light at a collision position with the first emitted electron and a collision position with the second emitted electron, and
an imaging element that images the light emitting element,
an output of the correction detector includes a captured image for correction captured using the imaging element,
the first detector includes an element that detects light emission in a first detection range of the light emitting element in order to detect the first emitted electron,
the second detector includes an element that detects light emission in a second detection range of the light emitting element in order to detect the second emitted electron, and
specifying the first crosstalk amount in the (B) includes specifying an amount of the second emitted electron included in the first detection range based on the captured image for correction.

4. The processor system according to claim 3, wherein
the charged particle beam irradiation system further irradiates a third region on the sample surface with a third charged particle beam,
the detection system further includes a third detector that detects a third emitted electron emitted from the third region through a part of the correction detector and outputs a third signal,
the third detector includes an element that detects light emission in a third detection range of the light emitting element for detecting the third emitted electron,
the processor
(D) specifies a second crosstalk amount from the third emitted electron to the first signal based on an output of the correction detector, regarding the amount detected by the first detector and
(E) corrects the first brightness based on the second crosstalk amount, and
specifying the second crosstalk amount in the (D) includes specifying an amount of the third emitted electrons included in the first detection range based on the captured image for correction.

5. The processor system according to claim 4, wherein
the captured image for correction has
a first image region corresponding to the first detection range of the light emitting element,
a second image region corresponding to the second detection range of the light emitting element, and
a third image region corresponding to the third detection range of the light emitting element, and
the processor
in the (B), specifies the first crosstalk amount to a value greater than zero when a first light emitting region extending from the second image region into the first image region exists, and
in the (D), specifies the second crosstalk amount to a value greater than zero when a second light emitting region extending from the third image region into the first image region exists.

6. The processor system according to claim 5, wherein
the processor
(F) stores the second brightness acquired from the charged-particle microscope apparatus in the memory resource, and
(G) corrects the second brightness based on at least the first crosstalk amount.

7. The processor system according to claim 3, wherein
the controller generates the first image including the first pixel as generation of the first brightness of the first pixel, and generates the second image including the second pixel as generation of the second brightness of the second pixel, and
an imaging period of the captured image for correction imaged by the imaging element of the correction detector is a period matching a period of the first signal corresponding to the first image by the first detector or a period of detection of the first signal corresponding to the first pixel.

8. A correction method in a processor system that is able to communicate with a charged-particle microscope apparatus, wherein
the charged-particle microscope apparatus includes
a charged particle beam irradiation system that includes at least one charged particle source, and irradiates a first region on a sample surface with a first charged particle beam generated using the charged particle source while irradiating a second region on the sample surface with a second charged particle beam generated using the charged particle source,
a detection system including
a correction detector that detects a first emitted electron emitted from the first region and a second emitted electron emitted from the second region,
a first detector that detects the first emitted electron through a part of the correction detector and outputs a first signal, and
a second detector that detects the second emitted electron through a part of the correction detector and outputs a second signal, and
a controller that generates a first brightness of a first pixel corresponding to a first position within the first region based on the first signal and generates a second brightness of a second pixel corresponding to a second position within the second region based on the second signal, wherein
the processor system includes one or more memory resources and one or more processors, and
the correction method executed by the processor comprises
(A) storing the first brightness and an output of the correction detector acquired from the charged-particle microscope apparatus in the memory resource,
(B) specifying a first crosstalk amount from the second emitted electron to the first signal, regarding the amount detected by the first detector, based on the output of the correction detector, and
(C) correcting the first brightness based on the first crosstalk amount.

9. The correction method according to claim 8, wherein
the controller generates a first image including the first pixel as generation of the first brightness of the first pixel, and generates a second image including the second pixel as generation of the second brightness of the second pixel.

10. The correction method according to claim 8, wherein
the correction detector includes
a light element that emits light at a collision position with the first emitted electron and a collision position with the second emitted electron, and
an imaging element that images the light emitting element,
an output of the correction detector includes a captured image for correction captured using the imaging element,
the first detector includes an element that detects light emission in a first detection range of the light emitting element in order to detect the first emitted electron,
the second detector includes an element that detects light emission in a second detection range of the light emitting element in order to detect the second emitted electron, and
specifying the first crosstalk amount in the (B) includes specifying an amount of the second emitted electron included in the first detection range based on the captured image for correction.

11. The correction method according to claim 10, wherein
the charged particle beam irradiation system further irradiates a third region on the sample surface with a third charged particle beam,
the detection system further includes a third detector that detects a third emitted electron emitted from the third region through a part of the correction detector and outputs a third signal,
the third detector includes an element that detects light emission in a third detection range of the light emitting element for detecting the third emitted electron,
the correction method executed by the processor further comprises
(D) specifying a second crosstalk amount from the third emitted electron to the first signal based on an output of the correction detector regarding the amount detected by the first detector, and
(E) correcting the first brightness based on the second crosstalk amount, and
specifying the second crosstalk amount in the (D) includes specifying an amount of the third emitted electrons included in the first detection range based on the captured image for correction.

12. The correction method according to claim 11, wherein
the captured image for correction has
a first image region corresponding to the first detection range of the light emitting element,
a second image region corresponding to the second detection range of the light emitting element, and
a third image region corresponding to the third detection range of the light emitting element,
the correction method executed by the processor further comprises
in the (B), specifying the first crosstalk amount to a value greater than zero when a first light emitting region extending from the second image region into the first image region exists, and
in the (D), specifying the second crosstalk amount to a value greater than zero when a second light emitting region extending from the third image region into the first image region exists.

13. The correction method according to claim 12, wherein
the correction method executed by the processor further comprises
(F) storing the second brightness acquired from the charged-particle microscope apparatus in the memory resource, and
(G) correcting the second brightness based on at least the first crosstalk amount.

14. The correction method according to claim 11, wherein
the controller generates the first image including the first pixel as generation of the first brightness of the first pixel, and generates the second image including the second pixel as generation of the second brightness of the second pixel, and
an imaging period of the captured image for correction imaged by the imaging element of the correction detector is a period matching a period of the first signal corresponding to the first image by the first detector or a period of detection of the first signal corresponding to the first pixel.

15. A correction program that causes a processor system to execute the correction method according to claim 8.
